(19) United States
(12) Patent Application Publication
(10) Pub. No.: US 2013/0043922 A1
(43) Pub. Date: Feb. 21, 2013

(54) SUPPLY COLLAPSE DETECTION CIRCUIT

(71) Applicant: Ankit Srivastava, San Diego, CA (US)

(72) Inventor: Ankit Srivastava, San Diego, CA (US)

(73) Assignee: QUALCOMM INCORPORATED, San Diego, CA (US)

(21) Appl. No.: 13/363,215

(22) Filed: Jan. 31, 2012

Related U.S. Application Data
(60) Provisional application No. 61/525,066, filed on Aug. 18, 2011.

(51) Int. Cl. H03K 3/353; H03L 5/00; H03K 3/00

(52) U.S. Cl. 327/208; 327/199; 327/333

(57) ABSTRACT

A supply collapse detection circuit is described. The supply collapse detection circuit includes threshold detection circuitry coupled to a first power supply and to a second power supply that provides a second voltage. The supply collapse detection circuit also includes supply collapse output circuitry coupled to the threshold detection circuitry to receive a detection signal when the second voltage drops. The supply collapse output circuitry includes an output node to provide an output signal indicating the drop. The supply collapse detection circuit additionally includes feedback circuitry coupled to the first power supply, to the threshold detection circuitry and to the supply collapse output circuitry. The feedback circuitry reduces leakage when the second voltage drops.

### CLAIM OF PRIORITY UNDER 35 U.S.C. §119

The present application for patent claims priority to Provisional Application No. 61/525,066 entitled “A SUPPLY COLLAPSE DETECTION CIRCUIT” filed Aug. 18, 2011, and assigned to the assignee hereof and hereby expressly incorporated by reference herein.

### TECHNICAL FIELD

The present disclosure relates generally to electronic devices. More specifically, the present disclosure relates to a supply collapse detection circuit.

### BACKGROUND

Electronic devices (cellular telephones, wireless modems, computers, digital music players, Global Positioning System units, Personal Digital Assistants, gaming devices, etc.) have become a part of everyday life. Small electronic devices are now placed in everything from automobiles to housing locks.

The complexity of electronic devices has increased dramatically in the last few years. For example, many electronic devices have one or more processors that help control the device, as well as a number of digital circuits to support the processor and other parts of the device. Furthermore, the size of electronic devices has diminished to the point where a multitude of transistors may be placed on a very small integrated circuit. Power consumption for electronic devices has also diminished.

Although the size and power consumption of electronic devices have been reduced, further gains in size reduction and power efficiency are being sought. Reductions in power are particularly important for mobile electronic devices that use battery power to function. Additionally, minimal sizes for electronic circuits (included in electronic devices) are being sought as smaller form factors may be appealing to consumers or gains in chip real estate may be dedicated to improved functionality. As can be observed from the foregoing discussion, systems and methods that help to detect a change in a power supply and reduce leakage may be beneficial.

### SUMMARY

A supply collapse detection circuit is disclosed. The supply collapse detection circuit includes threshold detection circuitry coupled to a first power supply and to a second power supply that provides a second voltage. The supply collapse detection circuit also includes supply collapse output circuitry coupled to the threshold detection circuitry to receive a detection signal when the second voltage drops. The supply collapse output circuitry includes an output node to provide an output signal indicating the drop. The supply collapse detection circuit additionally includes feedback circuitry coupled to the first power supply, to the threshold detection circuitry and to the supply collapse output circuitry. The feedback circuitry reduces leakage when the second voltage drops. The supply collapse detection circuit may also include a resistor coupled between the feedback circuitry and the threshold detection circuitry. The supply collapse detection circuit may be an integrated circuit.

The output node may be coupled to a level shifter circuit. The output signal may be provided to the level shifter circuit to reduce leakage from the level shifter circuit.

The threshold detection circuitry may include an inverter circuit. The inverter circuit may include a P-channel metal-oxide-semiconductor field-effect-transistor (PMOS). A gate of the PMOS may be coupled to the second power supply. A source of the PMOS may be coupled to the feedback circuitry. A body of the PMOS may be coupled to the first power supply. A drain of the PMOS may be coupled to the supply collapse output circuitry. The inverter circuit may also include an N-channel metal-oxide-semiconductor field-effect transistor (NMOS). A gate of the NMOS may be coupled to the second power supply and to the gate of the PMOS. A source of the NMOS may be coupled to a ground. A body of the NMOS may be coupled to the ground. A drain of the NMOS may be coupled to the supply collapse output circuitry and to the drain of the PMOS.

The feedback circuitry may include a feedback transistor. The feedback transistor may include an N-channel metal-oxide-semiconductor field-effect transistor (NMOS). A gate of the NMOS may be coupled to the supply collapse output circuitry. A source of the NMOS may be coupled to the threshold detection circuitry. A body of the NMOS may be coupled to a ground. A drain of the NMOS may be coupled to the first power supply.

The supply collapse output circuitry may include a latch. The latch may include an inverter that is coupled to the first power supply. The latch may also include a P-channel metal-oxide-semiconductor field-effect-transistor (PMOS). A gate of the PMOS may be coupled to an output of the inverter. A source of the PMOS may be coupled to the first power supply. A body of the PMOS may be coupled to the first power supply. A drain of the PMOS may be coupled to an input of the inverter.

The supply collapse detection circuit may also include a capacitor. The capacitor may include a P-channel metal-oxide-semiconductor field-effect-transistor (PMOS). A gate of the PMOS may be coupled to a ground. A source of the PMOS may be coupled to a drain of the PMOS, to the feedback circuitry and to the threshold detection circuitry.

The supply collapse detection circuit may also include a hysteresis circuit. The hysteresis circuit may include a first N-channel metal-oxide-semiconductor field-effect transistor (NMOS). A gate of the first NMOS may be coupled to the second power supply and to the threshold detection circuitry. A source of the first NMOS may be coupled to a ground. A body of the first NMOS may be coupled to the ground. A drain of the first NMOS may be coupled to the threshold detection circuitry. The hysteresis circuit may also include a second NMOS. A gate of the second NMOS may be coupled to the latch and to the threshold detection circuitry. A source of the second NMOS may be coupled to the drain of the first NMOS. A body of the second NMOS may be coupled to the ground and a drain of the NMOS may be coupled to the first power supply.

A method for providing a power supply collapse signal is also disclosed. The method includes applying a first voltage and a second voltage to threshold detection circuitry. The method also includes detecting when the second voltage drops to produce a detection signal. The method further includes causing supply collapse output circuitry to generate an output signal indicating the drop based on the detection signal. The method additionally includes switching feedback circuitry to reduce leakage when the second voltage drops.

An apparatus for providing a power supply collapse signal is also disclosed. The apparatus includes means for applying a first voltage and a second voltage to threshold detection circuitry. The apparatus also includes means for detecting when the second voltage drops to produce a detection signal. The apparatus further includes means for causing supply collapse output circuitry to generate an output signal indicating the drop based on the detection signal. The apparatus additionally includes means for switching feedback circuitry to reduce leakage when the second voltage drops.

A computer-program product for providing a power supply collapse signal is also disclosed. The computer-program product includes a non-transitory tangible computer-readable medium with instructions. The instructions include code for causing a circuit to apply a first voltage and a second voltage to threshold detection circuitry. The instructions also include code for causing the circuit to detect when the second voltage drops to produce a detection signal. The instructions further include code for causing the circuit to cause supply collapse output circuitry to generate an output signal indicating the drop based on the detection signal. The instructions additionally include code for causing the circuit to switch feedback circuitry to reduce leakage when the second voltage drops.

### BRIEF DESCRIPTION OF THE DRAWINGS

FIG. 1 is a block diagram illustrating one example of a circuit that may suffer from heavy leakage;

FIG. 2 is a block diagram illustrating one configuration of a supply collapse detection circuit;

FIG. 3 is a block diagram illustrating a more specific configuration of a supply collapse detection circuit;

FIG. 4 is a graph illustrating one example of a transient response of a supply collapse detection circuit;

FIG. 5 is a graph illustrating another example of a transient response of a supply collapse detection circuit;

FIG. 6 is a block diagram illustrating another more specific configuration of a supply collapse detection circuit;

FIG. 7 is a graph illustrating one example of a comparison between supply collapse detection circuits;

FIG. 8 is a block diagram illustrating another more specific configuration of a supply collapse detection circuit;

FIG. 9 is a graph illustrating an example of a transient response of a supply collapse detection circuit with an added hysteresis circuit;

FIG. 10 is a block diagram illustrating another more specific configuration of a supply collapse detection circuit;

FIG. 11 is a block diagram illustrating one configuration of an electronic device in which one or more supply collapse detection circuits may be implemented;

FIG. 12 is a block diagram illustrating one configuration of an electronic device in which a supply collapse detection circuit may be implemented;

FIG. 13 is a flow diagram illustrating one configuration of a method for providing a power supply collapse signal;

FIG. 14 is a flow diagram illustrating a more specific configuration of a method for providing a power supply collapse signal;

FIG. 15 is a block diagram illustrating one configuration of several components in a wireless communication device in which one or more supply collapse detection circuits may be implemented; and

FIG. 16 illustrates various components that may be utilized in an electronic device.

### DETAILED DESCRIPTION

The systems and methods disclosed herein describe a supply collapse detection circuit or power collapse detection circuit. The power collapse detection circuit may detect when a voltage drops. For example, when power, a voltage or a voltage supply drops, the power collapse detection circuit may output a signal indicating the drop in power or voltage. As used herein, the terms “collapse” (and variations thereof) and “drop” (and variations thereof) may denote a reduction in power or voltage. The reduction may be any reduction and/or a certain amount of reduction (e.g., a reduction in an amount of volts). It should be noted that the terms “collapse” and “drop” (and variations thereof) may be used synonymously herein.

In one configuration, when a digital power supply is collapsed, there may be heavy leakage in level shifters used to level shift a signal from a digital to an analog domain. A power collapse detection circuit may be used to disable the level shifters when a digital power supply is collapsed to save power.

In one configuration, a power or supply collapse detection circuit may be included in a supply-independent level shifter. For example, the systems and methods disclosed herein may be used in conjunction with a power management integrated circuit (PMIC), coder/decoder (e.g., codec) and/or data converters (e.g., digital-to-analog converters (DACs) and/or analog-to-digital converters (ADCs)). In some configurations, the power or supply collapse detection circuit may be used with one or more level shifters.

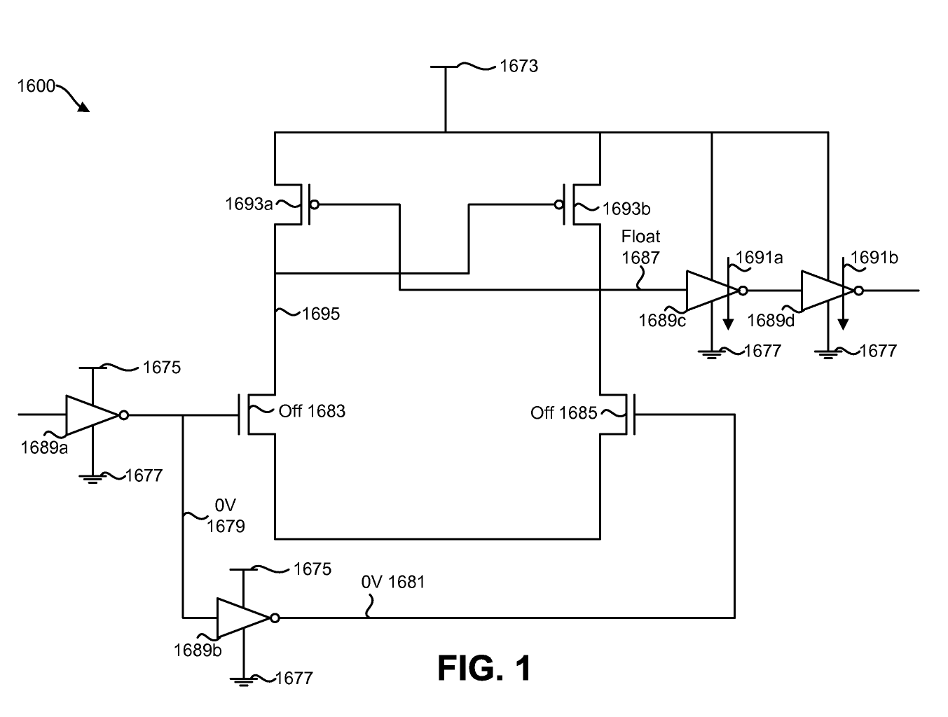

FIG. 1 is a block diagram illustrating one example of a circuit 1600 that may suffer from heavy leakage 1691a-b. The circuit 1600 may include four inverters 1689a-d, two p-channel metal-oxide semiconductor field-effect transistors (PMOS) 1693a-b and two n-channel metal-oxide semiconductor field-effect transistors (NMOS) 1683. The circuit 1600 (e.g., inverters 1689c-d) may be coupled to a first voltage 1693 (supplied by an analog or “high” voltage supply, for example). The circuit 1600 (e.g., inverters 1689a-b) may be also be coupled to a second voltage 1675 (supplied by a digital or “low” voltage supply, for example). The circuit 1600 or inverters 1689a-d may be coupled to a ground 1677.

The example illustrated in FIG. 1 illustrates the circuit 1600 in a state that may produce heavy current leakage 1691a-b. For instance, the second voltage 1675 supplied by the digital supply may be cut off or reduced to 0 volts (V). When this occurs, the output 1679 of the first inverter 1689a and the output 1681 of the second inverter 1689b may be reduced to 0V. When this occurs, the NMOS transistors 1683, 1685 are placed in an off state. In this state, the drain 1695 of the first PMOS transistor 1693a is at a voltage that is approximately equal to the first voltage 1673 supplied by the analog power supply. Furthermore, the gate of the first PMOS transistor 1693a or input to the third inverter 1689c is placed in a floating state 1687. In this floating state, the third and fourth inverters 1689c-d exhibit heavy current leakage 1691a-b. The leakage 1691a-b may cause the circuit 1600 to waste power or electrical energy.

The leakage illustrated by the example in FIG. 1 may occur in level-up shifters. In one configuration, for instance, there may be hundreds of level shifters used in circuitry that leads to heavy leakage from a supply during power collapse. Level-up shifters used from digital to analog domains (e.g., between digital and analog components) may suffer from such a leakage issue when a digital supply (e.g., lower voltage supply) is not available while an analog supply (e.g., higher voltage supply) is present. This leakage can happen even during a power up sequence if proper care is not taken. During power-up, the problem may be solved by following a particular power up sequence, where the digital supply is turned on prior to analog power up.

This problem may become severe when a chip is placed in sleep mode and a digital power supply is turned off in order to save power. In this case, a supply collapse signal (e.g., “freezeio” signal) may be generated to prevent leakage in the level shifters. The supply collapse signal (e.g., “freezeio” signal) may be powered by an “always-on” power supply and may be considered a design overhead. It should be noted that this “always-on” power supply may not be available in a chip in some configurations. Thus, extra pads may need to be added to bring in the “always-on” power supply in some cases.

In a first traditional approach, a controller (e.g., mobile station modem (MSM)) may send out a supply collapse signal (e.g., “freezeio” signal) to the level shifters before it can power down the digital supply. For example, this first approach uses a central power collapse circuit. Once a digital supply goes below 0.8 volts (V), the circuit generates a signal that can act as a “freezeio” (e.g., freeze input/output) signal for the level shifters. This circuit may be used as a central power collapse detection circuit, where the circuit provides the signal to multiple level shifters. One problem with this traditional approach is that the power collapse needs to be detected quickly, before level shifters start draining current from the analog supply, which could potentially affect the performance of some analog circuit. Another problem with this approach is that power may be burned in a comparator to achieve high bandwidth. Furthermore, this approach may demand constant direct current (DC) power consumption.

A second traditional power collapse detection circuit uses a diode ladder from the analog supply and current mirror action to reduce the leakage when the digital supply is present. In order to reduce a sizeable current in a second stage of this circuit when its input goes low, a current mirror is implemented that copies the second stage current into a first stage. This circuit has much higher bandwidth than the comparator-based approach described above. Furthermore, this circuit may also be used as part of a supply-independent level shifter.

The systems and methods disclosed herein describe a supply collapse detection circuit that may generate a freeze signal for level shifters in one configuration. For example, the supply collapse detection circuit described in accordance with the systems and methods disclosed herein may be used as part of a supply-independent level shifter. This supply collapse detection circuit may have fast detection similar to the second traditional power collapse detection circuit described above. However, this supply collapse detection circuit may use fewer component than both traditional approaches described above. Furthermore, this supply collapse detection circuit may be simpler to design. It should be noted that the supply collapse detection circuit described in accordance with the systems and methods disclosed herein may be used in other contexts and/or in conjunction with circuitry other than a level shifter.

In summary, a supply collapse detection circuit is described in accordance with the systems and methods disclosed herein. This supply collapse detection circuit may be used to detect power collapse (e.g., digital power collapse). This supply collapse detection circuit may also be used as part of a supply-independent level shifter with a few nanoamperes (nA) leakage. Furthermore, this circuit may have low leakage and/or fast response time as compared to traditional approaches or circuits. It should be noted that in a large chip, level shifters may be distributed all over the chip. This supply collapse detection circuit may be used as a local power collapse detection circuit.

Various configurations are now described with reference to the Figures, where like reference numbers may indicate functionally similar elements. The systems and methods as generally described and illustrated in the Figures herein could be arranged and designed in a wide variety of different configurations. Thus, the following more detailed description of several configurations, as represented in the Figures, is not intended to limit scope, as claimed, but is merely representative of the systems and methods.

It should be noted that the terms “couple,” “coupling,” “coupled” or other variations of the word couple as used herein may indicate either an indirect connection or a direct connection. For example, if a first component is “coupled” to a second component, the first component may be either indirectly connected (e.g., through another component) to the second component or directly connected to the second component. Additionally, it should be noted that as used herein, designating a component, element or entity (e.g., transistor, capacitor, resistor, power supply, circuit, etc.) as a “first,” “second,” “third” or “fourth” component may be arbitrary and is used to distinguish components for explanatory clarity. It should also be noted that labels used to designate a “second,” “third” or “fourth,” etc. do not necessarily imply that elements using preceding labels “first,” “second” or “third,” etc. are included or used. For example, simply because an element or component is labeled a “third” component does not necessarily imply that “first” and “second” elements or components exist or are used. In other words, the numerical labels (e.g., first, second, third, fourth, etc.) are labels used for ease in explanation and do not necessarily imply a particular number of elements or a particular structure. Thus, the components may be labeled or numbered in any manner.

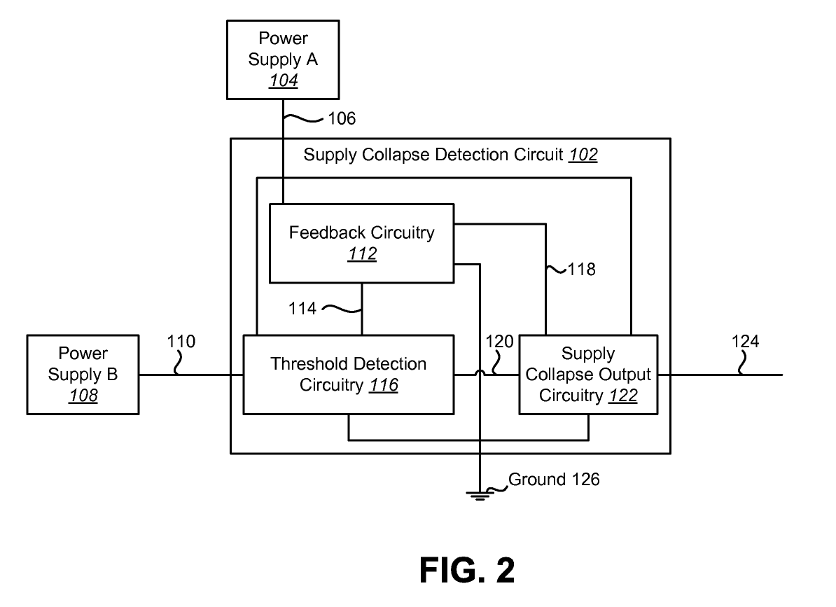

FIG. 2 is a block diagram illustrating one configuration of a supply collapse detection circuit 102. The supply collapse detection circuit 102 may detect a drop, reduction or collapse in power, voltage or voltage supply. The supply collapse detection circuit 102 may be coupled to power supply A 104 and power supply B 108. Power supply A 104 supplies a first voltage 106 to the supply collapse detection circuit 102. Power supply B 108 supplies a second voltage 110 to the supply collapse detection circuit 102. The supply collapse detection circuit 102 may also be coupled to ground 126. The ground 126 may be a reference point in relation to which electrical potential (e.g., voltages 106, 110) may exist. Additionally or alternatively, ground 126 may provide a common return path for electrical charge in a circuit (e.g., the supply collapse detection circuit 102).

In one configuration, the first voltage 106 may be higher than the second voltage 110. For example, power supply A 104 may be a power supply circuit that provides a (first) voltage 106 to analog components or circuits of a device (e.g., electronic device, circuit, chip, etc.) that require a higher voltage to function. For instance, the first voltage 106 provided by power supply A 104 may be 1.8V or 2V. In some cases, power supply A 104 may be referred to as an “analog supply.”

However, power supply B 108 may be a power supply that provides a (second) voltage 110 to digital components or circuits of a device (e.g., electronic device, circuit, chip, etc.) that require a lower voltage to function. In some cases, power supply B 108 may be referred to as a “digital supply.” For instance, the second voltage 110 provided by power supply B 108 may be 1.2V. In some configurations, power supply A 104 and power supply B 108 may provide voltages 106, 110 from the same power source, such as a battery and/or a power outlet.

The supply collapse detection circuit 102 may provide an output signal (e.g., a freeze signal) at an output node 124 that indicates when power supply B 108 or the second voltage 110 has dropped or collapsed. As used herein, the terms “collapse,” “drop” and variations thereof may refer to when power or voltage is cut off or diminished. For example, power supply B 108 may be cut off from providing the second voltage 110 to the supply collapse detection circuit 102 and/or other circuits. Thus, for example, the second voltage 110 may drop or be diminished. The supply collapse detection circuit 102 may detect when this collapse has occurred and provide the output signal indicating that the collapse has occurred.

In one configuration, the output signal (from the output node 124) may be provided to one or more level shifter circuits. In one example, the supply collapse detection circuit 102 may be included in an electronic device (e.g., cell phone) that uses analog and digital components. In order to conserve energy (e.g., battery charge), the electronic device may cut off power to one or more digital circuits such as level shifter circuits, thereby placing them into a sleep mode. However, if the digital supply (e.g., power supply B 108) is cut off while the analog supply (e.g., power supply A 104) is provided, the digital circuit(s) may be placed in a floating state and heavy leakage (e.g., current leakage) from the digital circuits (e.g., level shifter circuits) may occur. For instance, heavy leakage may occur as described in connection with FIG. 1 above. In order to reduce leakage, the output signal may be provided to the digital circuit(s), which may place the digital circuit(s) in a frozen state, thereby reducing leakage.

It should be noted that a level shifter circuit may be a circuit that changes the level (e.g., amplitude) of signals between circuits or components. For example, a digital component or circuit may output a signal with a lower amplitude than is needed to drive an analog component or circuit. A level-up shifter may shift or raise the digital component output amplitude up to a level used by the analog component, for instance.

The supply collapse detection circuit 102 may include feedback circuitry 112, threshold detection circuitry 116 and supply collapse output circuitry 122. Power supply A 104 may provide the first voltage 106 to the feedback circuitry 112, the threshold detection circuitry 116 and the supply collapse output circuitry 122. Power supply B 110 may provide the second voltage 110 to the threshold detection circuitry 116. The feedback circuitry 112, the threshold detection circuitry 116 and the supply collapse output circuitry 122 may be coupled to ground 126.

The feedback circuitry 112 may be coupled to power supply A 104, to the threshold detection circuitry 116 (through a second node 114 or coupling) and to the supply collapse output circuitry 122 (through a third node 118 or coupling). The threshold detection circuitry 116 may be coupled to power supply B 108, to the feedback circuitry 112 and to the supply collapse output circuitry 122 (through a first node 120 or coupling). The supply collapse output circuitry 122 may be coupled to the feedback circuitry 112 and the threshold detection circuitry 116. The supply collapse output circuitry 122 may also provide an output. In some configurations, the supply collapse output circuitry 122 may be coupled to another circuit or electronic device. For example, the supply collapse output circuitry 122 may be coupled to one or more level shifter circuits.

The threshold detection circuitry 116 may detect when the second voltage 110 has collapsed or diminished. For example, the threshold detection circuitry 116 may provide a detection signal (at the first node 120) to the supply collapse output circuitry 122. The detection signal may indicate that the second voltage 110 has collapsed or crossed a threshold.

The supply collapse output circuitry 122 may produce an output signal (at the output node 124) indicating a collapse in the second voltage 110. For example, the supply collapse output circuitry 122 may receive the detection signal from the threshold detection circuitry 116 and generate the output signal based on the detection signal. The output signal (at the output node 124 included in the supply collapse output circuitry 122) may be provided to one or more circuits. In some configurations, the output signal may trigger the one or more circuits to freeze operation in order to avoid leakage. The supply collapse output circuitry 122 may also provide a feedback signal to the feedback circuitry 112 (at the third node 118). In some configurations, the feedback signal at the third node 118 may be the output signal at the output node 124.

The feedback circuitry 112 may reduce leakage in the supply collapse detection circuit 102 when the second voltage 110 has collapsed. For example, the feedback circuitry 112 may receive the feedback signal (e.g., output signal) from the supply collapse output circuitry 122 and switch in order to avoid or reduce leakage.

In one configuration, the supply collapse detection circuit 102 may function as follows. When the second voltage 110 from power supply B 108 is present, the second node 114 between the feedback circuitry 112 and the threshold detection circuitry 116 may be charged to a voltage that is approximately the average of the first voltage 106 and the second voltage 110 (e.g., approximately the sum of the first voltage 106 and second voltage 110 divided by two). The output signal (e.g., output voltage) is then approximately equal to the first voltage 106. In this state, circuit leakage may be determined by the threshold detection circuitry 116 and the feedback circuitry 112.

When the second voltage 110 provided by power supply B 108 drops or collapses (e.g., crosses a threshold), the voltage at the second node 114 initially charges the first node 120 (between the threshold detection circuitry 116 and the supply collapse output circuitry 122) to a point where the supply collapse output circuitry 122 trips and the output signal (at the output node 124) is pulled to zero. The second node 114 may then be charged through the first node 120 by the supply collapse output circuitry 122. The output signal may be provided to the feedback circuitry 112 as a feedback signal. The feedback circuitry 112 may then switch (e.g., turn off) to reduce (e.g., avoid, prevent, etc.) leakage.

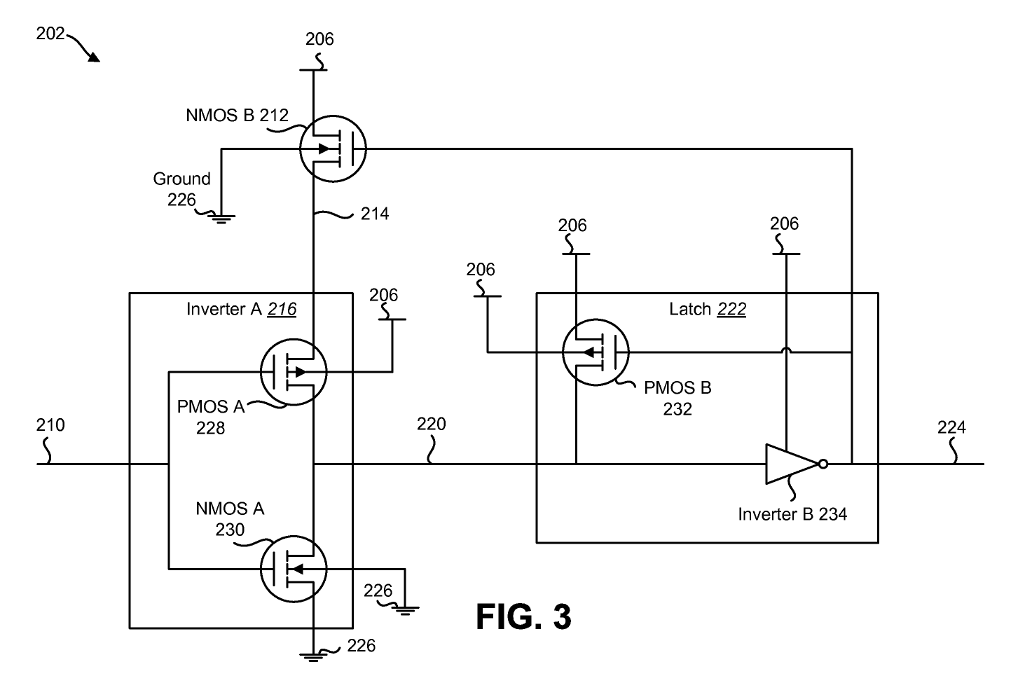

FIG. 3 is a block diagram illustrating a more specific configuration of a supply collapse detection circuit 202. The supply collapse detection circuit 202 may be coupled to a first power supply that supplies a first voltage 206 and a second power supply that supplies a second voltage 210. More specifically, the first power supply supplies a first voltage 206 and the second power supply supplies a second voltage 210 to the supply collapse detection circuit 202. The supply collapse detection circuit 202 may also be coupled to ground 226. The ground 226 may be a reference point in relation to which electrical potential (e.g., voltages 206, 210) may exist. Additionally or alternatively, ground 226 may provide a common return path for electrical charge in a circuit (e.g., the supply collapse detection circuit 202).

In one configuration, the first voltage 206 may be higher than the second voltage 210. For example, the first power supply may be a power supply circuit that provides a (first) voltage 206 to analog components or circuits of a device (e.g., electronic device, circuit, chip, etc.) that require a higher voltage to function. For instance, the first voltage 206 provided by the first power supply may be 1.8V or 2V. In some cases, the first power supply may be referred to as an “analog supply.”

The second power supply may be a power supply that provides a (second) voltage 210 to digital components or circuits of a device (e.g., electronic device, circuit, chip, etc.) that require a lower voltage to function. In some cases, the second power supply may be referred to as a “digital supply.” For instance, the second voltage 210 provided by the second power supply may be 1.2V. In some configurations, the first power supply and the second power supply may provide voltages 206, 210 from the same power source, such as a battery and/or a power outlet.

The supply collapse detection circuit 202 may provide an output signal (e.g., a freeze signal) at an output node 224 that indicates when the second power supply or the second voltage 210 has collapsed. For example, the second power supply may be cut off from providing the second voltage 210 to the supply collapse detection circuit 202 and/or other circuits. Thus, for example, the second voltage 210 may drop or be diminished. The supply collapse detection circuit 202 may detect when this collapse has occurred and provide the output signal (at the output node 224) indicating that the collapse has occurred.

In one configuration, the output signal may be provided to one or more level shifter circuits from the output node 224. In one example, the supply collapse detection circuit 202 may be included in an electronic device (e.g., cell phone) that uses analog and digital components. In order to conserve energy (e.g., battery charge), the electronic device may cut off power to one or more digital circuits such as level shifter circuits, thereby placing them into a sleep mode. However, if the digital supply (e.g., the second power supply) is cut off while the analog supply (e.g., the first power supply) is provided, the digital circuit(s) may be placed in a floating state and heavy leakage (e.g., current leakage) from the digital circuits (e.g., level shifter circuits) may occur. In order to reduce leakage, the output signal (from the output node 224) may be provided to the digital circuit(s), which may place the digital circuit(s) in a frozen state, thereby reducing leakage. The output signal may be referred to as a “freeze signal.” In one configuration, the freeze signal may be used to switch transistors (e.g., turn them off and/or on) in a level shifter, thereby freezing the level shifter and reducing leakage.

The supply collapse detection circuit 202 may include N-channel metal-oxide semiconductor field-effect transistor (NMOS) B 212, inverter A 216 and a latch 222. NMOS B 212 may be one example of the feedback circuitry 112 illustrated in FIG. 2. Inverter A 216 may be one example of the threshold detection circuitry 116 illustrated in FIG. 2. The latch 222 may be one example of the supply collapse output circuitry 122 illustrated in FIG. 2. The first power supply may provide the first voltage 206 to NMOS B 212, inverter A 216 and the latch 222. The second power supply 210 may provide the second voltage 210 to inverter A 216. NMOS B 212, inverter A 216 and the latch 222 may be coupled to ground 226. NMOS B 212 may be coupled to the first power supply (that supplies a first voltage 206), to inverter A 216 (through a second node 214 or coupling), to the latch 222 and to ground 226. More specifically, the drain of NMOS B 212 may be coupled to the first power supply, the body of NMOS B 212 may be coupled to ground 226, the source of NMOS B 212 may be coupled to inverter A 216 and the gate of NMOS B 212 may be coupled to the latch 222 (and to the output node 224).

In the configuration illustrated in FIG. 3, inverter A 216 includes p-channel metal-oxide semiconductor field-effect transistor (PMOS) A 228 and NMOS A 230. Inverter A 216 may be coupled to the second power supply, to NMOS B 212, to the latch 222 (through a first node 220 or coupling) and to ground 226. More specifically, the gate of PMOS A 228 may be coupled to the second power supply (that provides a second voltage 210), the source of PMOS A 228 may be coupled to the source of NMOS B 212, the body of PMOS A 228 may be coupled to the first power supply (that provides a first voltage 206) and the drain of PMOS A 228 may be coupled to NMOS A 230 and to the latch 222. The drain of NMOS A 230 may be coupled to the drain of PMOS A 228 and to the latch 222, the body of NMOS A 230 may be coupled to ground 226, the source of NMOS A 230 may be coupled to ground 226 and the gate of NMOS A 230 may be coupled to the second power supply (that provides a second voltage 210) and/or to the gate of PMOS A 228.

In the configuration illustrated in FIG. 3, the latch 222 includes PMOS B 232 and inverter B 234 (and the output node 224). The latch 222 may be coupled to NMOS B 212 and inverter A 216. More specifically, the gate of PMOS B 232 may be coupled to the gate of NMOS B 212 and the output node 224, the source of PMOS B 232 may be coupled to the first power supply (that provides a first voltage 206), the body of PMOS B 232 may be coupled to the first power supply (that provides a first voltage 206), the drain of PMOS B 232 may be coupled to the drain of PMOS A 228, to the drain of NMOS A 230 and to inverter B 234. The input to inverter B 234 may be coupled to the drain of PMOS A 228, to the drain of NMOS A 230 and to the drain of PMOS B 232. Inverter B 234 may be coupled to the first supply (that provides the first voltage 206). The output of inverter B 234 may be coupled to the gate of NMOS B 212 and to the gate of PMOS B 232 and may provide the output signal at the output node 224. In some configurations, the latch 222 (including the output node 224, for example) may be coupled to another circuit or electronic device. For example, the latch 222 may be coupled to one or more level shifter circuits.

For convenience in describing the functionality of the supply collapse detection circuit 202, the second node 214 may be referred to as node z, the first node 220 may be referred to as node x, and the output node 224 may be referred to as node y. Furthermore, the first voltage 206 may be referred to as V_{DDH} (e.g., higher voltage) and the second voltage 210 may be referred to as V_{DDL} (e.g., lower voltage).

In one configuration, the supply collapse detection circuit 202 may function as follows. When the second voltage V_{DDL} 210 from the second power supply is present, the second node z 214 (between NMOS B 212 and inverter A 216) may be charged to a voltage V_{z} that is approximately the average of the first voltage 206 and the second voltage 210 (e.g.,

$${V}_{z} = \frac{( {V}_{DDL} + {V}_{DDH} )}{2} ) .$$

The output voltage V_{y} (at the output node y 224) is then approximately equal to the first voltage V_{DDH} 206. In this state, circuit leakage may be determined by PMOS A 228 and NMOS B 212.

When the second voltage V_{DDL} 210 provided by the second power supply collapses or drops (beyond a threshold amount, for example), PMOS A 228 turns on and the voltage V_{z} at the second node z 214 initially charges the first node x 220 (between inverter A 216 and the latch 222) to a voltage Vₓ where the latch 222 trips and the output signal V_{y} at the output node y 224 is pulled to zero. The voltage V_{z} at the second node z 214 may then be charged through the first node x 220 (e.g., Vₓ) by PMOS B 232. In this condition, there may be little or no leakage since the output signal V_{y} is zero and the top part of the circuit 202 (e.g., NMOS B 212) is off.

More detail on one configuration of the supply collapse detection circuit 202 is given hereafter. The current for NMOS B 212 may be expressed as illustrated in Equation (1). It should be noted that Equation (1) is a leakage equation for when the transistor (e.g., NMOS B 212) is in a sub-threshold region.

$${I}_{dn} = {I}_{0 n} {e}^{( \frac{{V}_{gsn} - {V}_{tn}}{{k}_{n} {V}_{T}} )} \qquad ( 1 )$$

In Equation (1), I_{dn} is the current flowing from the drain to the source of NMOS B 212 and I_{On} is the current when the gate-to-source voltage of NMOS B 212 (V_{gsn}) is equal to the threshold voltage of NMOS B 212 (Vₜₙ) or V_{gsn}=Vₜₙ. Furthermore, kₙ is a slope factor of NMOS B 212 given by

$${k}_{n} = 1 + \frac{{C}_{dn}}{{C}_{oxn}} ,$$

where C_{cdn} is the depletion layer capacitance of NMOS B 212 and Cₒₓₙ is the oxide layer capacitance of NMOS B 212. Additionally, V_{T} is the thermal voltage given by

$${V}_{T} = \frac{k T}{q} ,$$

where k is the Boltzmann constant (in Joules/Kelvin), T is the absolute temperature (in Kelvin (K)) and q is the electrical charge magnitude of an electron.

The current for PMOS A 228 may be expressed as illustrated in Equation (2).

$${I}_{dp} = {I}_{0 p} {e}^{( \frac{{V}_{sgp} - {V}_{tp}}{{k}_{p} {V}_{T}} )} \qquad ( 2 )$$

In Equation (2), I_{dp} is the current flowing from the source to the drain of PMOS A 228 and Iₒₚ is the current when the source-to-gate voltage of PMOS A 228 (V_{sgp}) is equal to the threshold voltage of PMOS A 228 (Vₜₚ) or V_{sgp}=Vₜₚ. It should be noted that Vₜₚ may be positive. Furthermore, kₚ is a slope factor of PMOS A 228 given by

$${k}_{p} = 1 + \frac{{C}_{dp}}{{C}_{oxp}} ,$$

where C_{dp} is the depletion layer capacitance of PMOS A 228 and Cₒₓₚ is the oxide layer capacitance of PMOS A 228. Additionally, V_{T} is the thermal voltage given by

$${V}_{T} = \frac{k T}{q} ,$$

where k is the Boltzmann constant (in Joules/Kelvin), T is the absolute temperature (in Kelvin (K)) and q is the electrical charge magnitude of an electron.

As can be observed in FIG. 3, I_{dn}=I_{dp}. Furthermore, the voltage at node z 214 (e.g., V_{z}) may be expressed as illustrated in Equation (3).

$${V}_{z} = \frac{( {V}_{DDH} - {V}_{tn} )}{2} + \frac{( {V}_{DDL} + {V}_{tp} )}{2} \qquad ( 3 )$$

Assuming that Vₜₙ=Vₜₚ, V_{z} may be expressed as illustrated in Equation (4).

$${V}_{z} \approx \frac{{V}_{DDH} + {V}_{DDL}}{2} \qquad ( 4 )$$

As illustrated in FIG. 3, the supply collapse detection circuit 202 may use inverter A 216, whose supply is controlled by the feedback transistor (NMOS B 212) to reduce leakage when the second voltage 210 is up. The body effect on both NMOS B 212 and PMOS A 228 may help to reduce the leakage.

In one configuration, the supply collapse detection circuit 202 may use a “digital” supply of 1.2V 210 and an “analog” supply ranging from 1.62V to 2.3V 206. With the body effect, a minimum threshold voltage for PMOS A 228 may be 0.63V and a minimum threshold voltage for NMOS B 212 may be 0.82V. This may be at a highest assumed temperature (e.g., around 125° Celsius (C)) and when both NMOS and PMOS are faster in the process, for example.

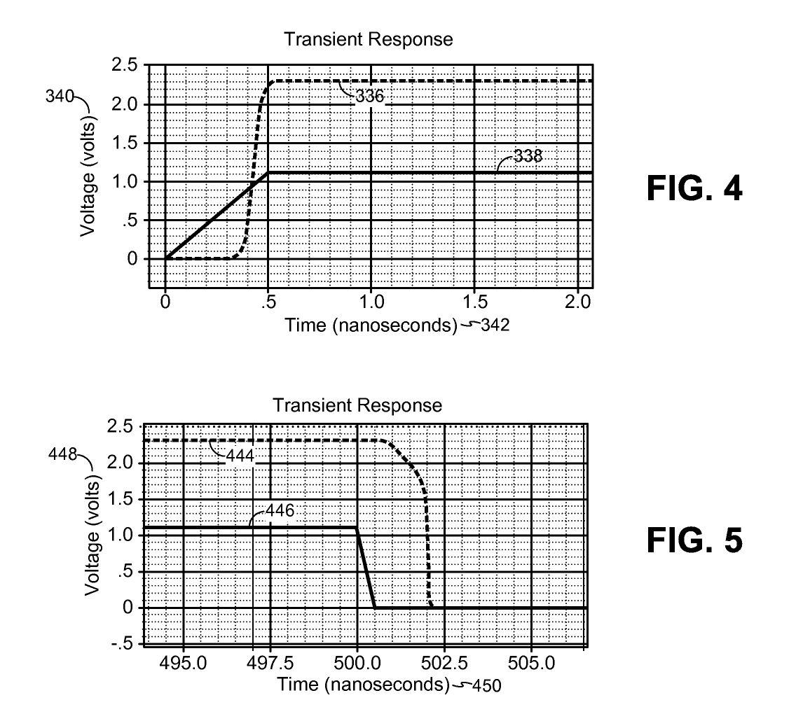

FIG. 4 is a graph illustrating one example of a transient response of a supply collapse detection circuit 102. The graph illustrates an input voltage 338 (e.g., a second voltage 110) and an output voltage or signal 336 (e.g., an output signal at the output node 124). The input voltage 338 and the output voltage or signal 336 are illustrated in volts 340 along the vertical axis and in time (nanoseconds) 342 along the horizontal axis.

More specifically, the graph in FIG. 4 illustrates a low-to-high transient response of a supply collapse detection circuit 102. As can be observed in FIG. 4, when the input voltage 338 (e.g., second voltage 110) increases or ramps up to 1.1V, the output voltage or signal 336 increases to 2.3V.

FIG. 5 is a graph illustrating another example of a transient response of a supply collapse detection circuit 102. The graph illustrates an input voltage 446 (e.g., a second voltage 110) and an output voltage or signal 444 (e.g., an output signal at the output node 124). The input voltage 446 and the output voltage or signal 444 are illustrated in volts 448 along the vertical axis and in time (nanoseconds) 450 along the horizontal axis.

More specifically, the graph in FIG. 5 illustrates a high-to-low transient response of a supply collapse detection circuit 102. As can be observed in FIG. 5, when the input voltage 446 (e.g., second voltage 110) drops, decreases or collapses to 0V, the output voltage or signal 444 decreases to 0V. Table (1) below illustrates some test or simulation results for one example of a supply collapse detection circuit 102. In particular, Table (1) illustrates minimum, typical and maximum results for leakage in nanoamperes (nA) and delay in nanoseconds (ns) across ranges of process, voltage and temperature (PVT). The leakage values illustrated in Table (1) may reflect the current consumption of the circuit 102 during “normal” operation, or when power supply B 108 (e.g., a digital supply) is turned on.

TABLE (1)

| | Leakage (nA) | Delay (ns) |
|---|---|---|
| Min | 0.12 | 2.8 |
| Typical | 0.3 | 6 |
| Max | 14 | 44 |

In Table (1), the delay values are measured from the time that an input voltage starts to drop to the time that an output voltage has completely dropped.

A simulation of one example of the supply collapse detection circuit 102 was performed. At a typical corner, the simulation showed a healthy 300 millivolt (mV) hysteresis in the system. For example, the first crossing point in a hysteresis sweep (from low to high) between an input voltage and an output voltage occurred at approximately 645.8 mV and 2.691 us and the second crossing point (from high to low) occurred at approximately 306.4 mV and 8.723 μs.

It should be noted that leakage and delay may have a trade-off between them. For example, leakage can be reduced by reducing the size of PMOS A 228 and NMOS B 212 at the cost of increased delay.

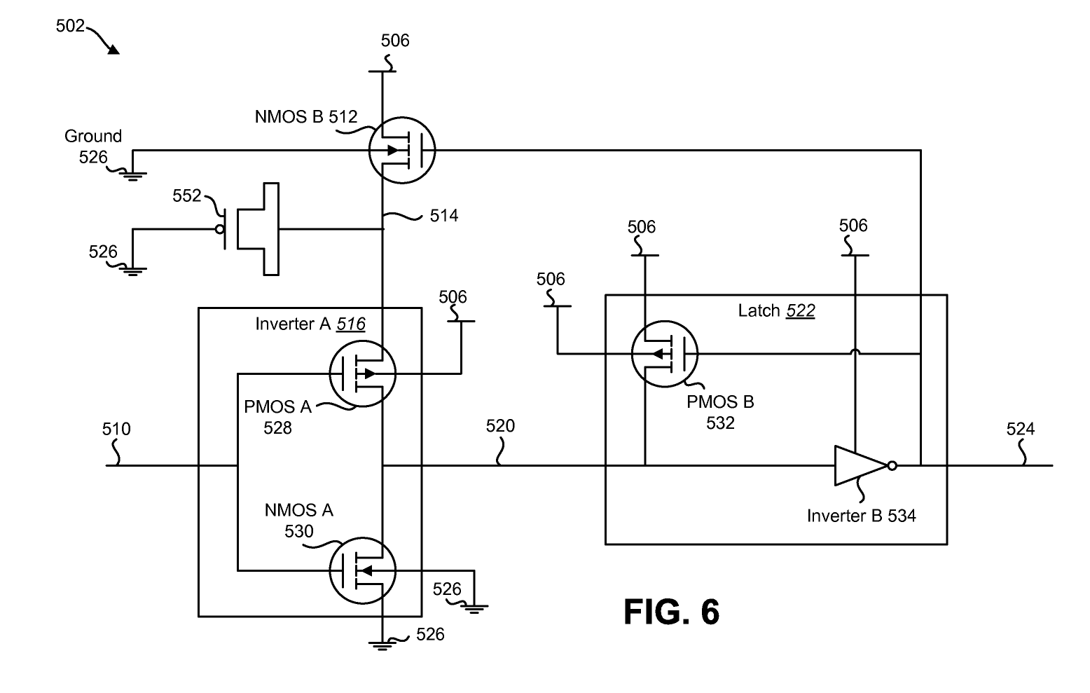

FIG. 6 is a block diagram illustrating another more specific configuration of a supply collapse detection circuit 502. The supply collapse detection circuit 502 may be coupled to a first power supply that supplies a first voltage 506 and a second power supply that supplies a second voltage 510. More specifically, the first power supply supplies a first voltage 506 and the second power supply supplies a second voltage 510 to the supply collapse detection circuit 502. The supply collapse detection circuit 502 may also be coupled to ground 526. The ground 526 may be a reference point in relation to which electrical potential (e.g., voltages 506, 510) may exist. Additionally or alternatively, ground 526 may provide a common return path for electrical charge in a circuit (e.g., the supply collapse detection circuit 502).

In one configuration, the first voltage 506 may be higher than the second voltage 510. For example, the first power supply may be a power supply circuit that provides a (first) voltage 506 to analog components or circuits of a device (e.g., electronic device, circuit, chip, etc.) that require a higher voltage to function. For instance, the first voltage 506 provided by the first power supply may be 1.8V or 2V. In some cases, the first power supply may be referred to as an “analog supply.”

The second power supply may be a power supply that provides a (second) voltage 510 to digital components or circuits of a device (e.g., electronic device, circuit, chip, etc.) that require a lower voltage to function. In some cases, the second power supply may be referred to as a “digital supply.” For instance, the second voltage 510 provided by the second power supply may be 1.2V. In some configurations, the first power supply and the second power supply may provide voltages 506, 510 from the same power source, such as a battery and/or a power outlet.

The supply collapse detection circuit 502 may provide an output signal (e.g., a freeze signal) at an output node 524 that indicates when the second power supply or the second voltage 510 has collapsed. For example, the second power supply may be cut off from providing the second voltage 510 to the supply collapse detection circuit 502 and/or other circuits. Thus, for example, the second voltage 510 may drop or be diminished. The supply collapse detection circuit 502 may detect when this collapse has occurred and provide the output signal (at the output node 524) indicating that the collapse has occurred.

In one configuration, the output signal may be provided to one or more level shifter circuits from the output node 524. In one example, the supply collapse detection circuit 502 may be included in an electronic device (e.g., cell phone) that uses analog and digital components. In order to conserve energy (e.g., battery charge), the electronic device may cut off power to one or more digital circuits such as level shifter circuits, thereby placing them into a sleep mode. However, if the digital supply (e.g., the second power supply) is cut off while the analog supply (e.g., the first power supply) is provided, the digital circuit(s) may be placed in a floating state and heavy leakage (e.g., current leakage) from the digital circuits (e.g., level shifter circuits) may occur. In order to reduce leakage, the output signal (from the output node 524) may be provided to the digital circuit(s), which may place the digital circuit(s) in a frozen state, thereby reducing leakage.

The supply collapse detection circuit 502 may include N-channel metal-oxide semiconductor field-effect transistor (NMOS) B 512, inverter A 516 and a latch 522. NMOS B 512 may be one example of the feedback circuitry 112 illustrated in FIG. 2. Inverter A 516 may be one example of the threshold detection circuitry 116 illustrated in FIG. 2. The latch 522 may be one example of the supply collapse output circuitry 122 illustrated in FIG. 2. The first power supply may provide the first voltage 506 to NMOS B 512, inverter A 516 and the latch 522. The second power supply may provide the second voltage 510 to inverter A 516. NMOS B 512, inverter A 516 and the latch 522 may be coupled to ground 526.

NMOS B 512 may be coupled to the first power supply (that supplies a first voltage 506), to inverter A 516 (through a second node 514 or coupling) to the latch 522 and to ground 526. More specifically, the drain of NMOS B 512 may be coupled to the first power supply, the body of NMOS B 512 may be coupled to ground 526, the source of NMOS B 512 may be coupled to inverter A 516 and the gate of NMOS B 512 may be coupled to the latch 522 (and to the output node 524).

In the configuration illustrated in FIG. 6, inverter A 516 includes p-channel metal-oxide semiconductor field-effect transistor (PMOS) A 528 and NMOS A 530. Inverter A 516 may be coupled to the second power supply, to NMOS B 512, to the latch 522 (through a first node 520 or coupling) and to ground 526. More specifically, the gate of PMOS A 528 may be coupled to the second power supply (that provides a second voltage 510), the source of PMOS A 528 may be coupled to the source of NMOS B 512, the body of PMOS A 528 may be coupled to the first power supply (that provides a first voltage 506) and the drain of PMOS A 528 may be coupled to NMOS A 530 and to the latch 522. The drain of NMOS A 530 may be coupled to the drain of PMOS A 528 and to the latch 522, the body of NMOS A 530 may be coupled to ground 526, the source of NMOS A 530 may be coupled to ground 526 and the gate of NMOS A 530 may be coupled to the second power supply (that provides a second voltage 510) and/or to the gate of PMOS A 528.

In the configuration illustrated in FIG. 6, a capacitor 552 is coupled to ground 526, to NMOS B 512 and to inverter A 516. This capacitor 552 may be used in order to speed up (e.g., reduce the response time of) the supply collapse detection circuit 502. For example, the capacitor 552 may be added at a second node 514 (e.g., node z) to store charge when the second voltage 510 is up and to provide that charge when the second voltage 510 drops or collapses.

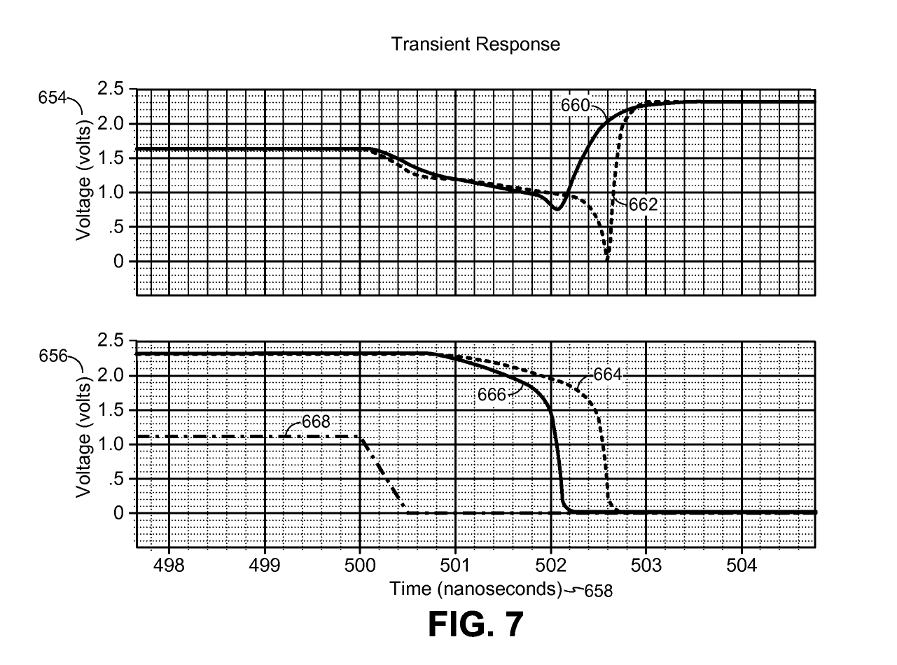

In one configuration, the capacitor 552 may be implemented using a PMOS. This may be referred to as a “holding cap.” For example, the gate of the PMOS may be coupled to ground 526 and the drain and source of the PMOS may be coupled together (and coupled to the source of NMOS B 512 and to the source of PMOS A 528 or to a second node 514). In other configurations, other kinds of capacitors (e.g., metal capacitors) may be used. However, a PMOS may be smaller and cheaper (for implementing the capacitor 552) in the supply collapse detection circuit 502 than other kinds of capacitors. One example of the performance improvement in the supply collapse detection circuit 502 as a result of using the capacitor 552 is illustrated in FIG. 7.

In the configuration illustrated in FIG. 6, the latch 522 includes PMOS B 532 and inverter B 534. The latch 522 may be coupled to NMOS B 512 and to inverter A 516 (through a first node 520). More specifically, the gate of PMOS B 532 may be coupled to the gate of NMOS B 512 and to the output node 524, the source of PMOS B 532 may be coupled to the first power supply (that provides a first voltage 506), the body of PMOS B 532 may be coupled to the first power supply (that provides the first voltage 506), the drain of PMOS B 532 may be coupled to the drain of PMOS A 528, to the drain of NMOS A 530 and to inverter B 534. The input to inverter B 534 may be coupled to the drain of PMOS A 528, to the drain of NMOS A 530 and to the drain of PMOS B 532. Inverter B 534 may be coupled to the first supply (that provides the first voltage 506). The output of inverter B 534 (e.g., the output node 524) may be coupled to the gate of NMOS B 512 and to the gate of PMOS B 532 and may provide the output signal at the output node 524. In some configurations, the latch 522 (e.g., output node 524) may be coupled to another circuit or electronic device. For example, the latch 522 may be coupled to one or more level shifter circuits.

FIG. 7 is a graph illustrating one example of a comparison between supply collapse detection circuits. The graph in FIG. 7 includes an upper and lower portion. The lower portion of the graph illustrates an input voltage 668 (e.g., a second voltage 210, 510). The lower portion also illustrates a first output voltage or signal 664 of a supply collapse detection circuit 202 without an added capacitor (e.g., capacitor 552) and a second output voltage or signal 666 of a supply collapse detection circuit 502 with an added capacitor (e.g., capacitor 552). The input voltage 668 and the output voltages or signals 664, 666 are illustrated in volts 656 along the vertical axis and in time (nanoseconds) 658 along the horizontal axis.

More specifically, the lower portion of the graph in FIG. 7 illustrates a high-to-low transient response of a supply collapse detection circuit 202 without an added capacitor and the high-to-low transient response of a supply collapse detection circuit 502 with an added capacitor (e.g., capacitor 552 at a second node 514 or node z). As can be observed in FIG. 7, the second output voltage or signal 666 in a supply collapse detection circuit 502 with the added capacitor (e.g., capacitor 552) decreases to 0V sooner than the first output voltage or signal 664 in a supply collapse detection circuit 202 without the added capacitor. Thus, for example, a capacitor 552 may be added at a second node 514 (e.g., node z) to store charge when a second voltage 510 (from a second power supply) is up and to provide that charge when the second voltage 510 drops or collapses. This may help to reduce the response time of a supply collapse detection circuit as illustrated in the lower portion of the graph in FIG. 7.

The upper portion of the graph illustrates a first voltage 662 at a second node (e.g., second node 214) of a supply collapse detection circuit 202 without an added capacitor. The upper portion also illustrates a second voltage 660 at a second node (e.g., second node 514) of a supply collapse detection circuit 502 with an added capacitor (e.g., capacitor 552). The second node voltages 660, 662 are illustrated in volts 654 along the vertical axis and in time (nanoseconds) 658 along the horizontal axis. As can be observed in FIG. 7, the second voltage or signal 660 at a second node 514 (e.g., node z) in a supply collapse detection circuit 502 with the added capacitor (e.g., capacitor 552) does not exhibit as large a voltage drop as the first voltage or signal 662 at a second node 214 in a supply collapse detection circuit 202 without the added capacitor.

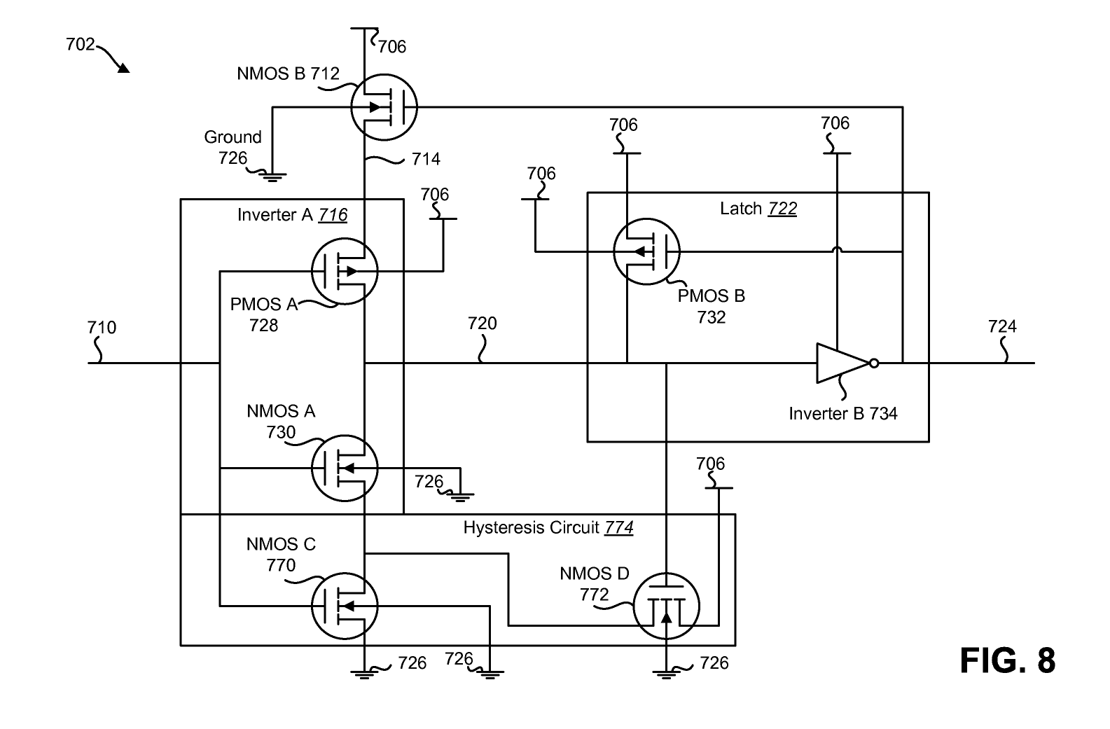

FIG. 8 is a block diagram illustrating another more specific configuration of a supply collapse detection circuit 702. The supply collapse detection circuit 702 may be coupled to a first power supply that supplies a first voltage 706 and a second power supply that supplies a second voltage 710. More specifically, the first power supply supplies a first voltage 706 and the second power supply supplies a second voltage 710 to the supply collapse detection circuit 702. The supply collapse detection circuit 702 may also be coupled to ground 726. The ground 726 may be a reference point in relation to which electrical potential (e.g., voltages 706, 710) may exist. Additionally or alternatively, ground 726 may provide a common return path for electrical charge in a circuit (e.g., the supply collapse detection circuit 702).

In one configuration, the first voltage 706 may be higher than the second voltage 710. For example, the first power supply may be a power supply circuit that provides a (first) voltage 706 to analog components or circuits of a device (e.g., electronic device, circuit, chip, etc.) that require a higher voltage to function. For instance, the first voltage 706 provided by the first power supply may be 1.8V or 2V. In some cases, the first power supply may be referred to as an “analog supply.”

The second power supply may be a power supply that provides a (second) voltage 710 to digital components or circuits of a device (e.g., electronic device, circuit, chip, etc.) that require a lower voltage to function. In some cases, the second power supply may be referred to as a “digital supply.” For instance, the second voltage 710 provided by the second power supply may be 1.2V. In some configurations, the first power supply and the second power supply may provide voltages 706, 710 from the same power source, such as a battery and/or a power outlet.

The supply collapse detection circuit 702 may provide an output signal (e.g., a freeze signal) at an output node 724 that indicates when the second power supply or the second voltage 710 has collapsed. For example, the second power supply may be cut off from providing the second voltage 710 to the supply collapse detection circuit 702 and/or other circuits. Thus, for example, the second voltage 710 may drop or be diminished. The supply collapse detection circuit 702 may detect when this collapse has occurred and provide the output signal (at the output node 724) indicating that the collapse has occurred.

In one configuration, the output signal may be provided to one or more level shifter circuits from the output node 724. In one example, the supply collapse detection circuit 702 may be included in an electronic device (e.g., cell phone) that uses analog and digital components. In order to conserve energy (e.g., battery charge), the electronic device may cut off power to one or more digital circuits such as level shifter circuits, thereby placing them into a sleep mode. However, if the digital supply (e.g., the second power supply) is cut off while the analog supply (e.g., the first power supply) is provided, the digital circuit(s) may be placed in a floating state and heavy leakage (e.g., current leakage) from the digital circuits (e.g., level shifter circuits) may occur. In order to reduce leakage, the output signal (from the output node 724) may be provided to the digital circuit(s), which may place the digital circuit(s) in a frozen state, thereby reducing leakage.

The supply collapse detection circuit 702 may include N-channel metal-oxide semiconductor field-effect transistor (NMOS) B 712, inverter A 716, a latch 722, and a hysteresis circuit 774 (including NMOS C 770 and NMOS D 772, for example). NMOS B 712 may be one example of the feedback circuitry 112 illustrated in FIG. 2. Inverter A 716 may be one example of the threshold detection circuitry 116 illustrated in FIG. 2. The latch 722 may be one example of the supply collapse output circuitry 122 illustrated in FIG. 2. The first power supply may provide the first voltage 706 to NMOS B 712, inverter A 716, the latch 722, and to the hysteresis circuit 774. The second power supply may provide the second voltage 710 to inverter A 716 and to the hysteresis circuit 774. NMOS B 712, the hysteresis circuit 774 (e.g., NMOS C 770 and NMOS D 772) and the latch 722 may be coupled to ground 726.

NMOS B 712 may be coupled to the first power supply (that supplies a first voltage 706), to inverter A 716 (through a second node 714 or coupling) to the latch 722 and to ground 726. More specifically, the drain of NMOS B 712 may be coupled to the first power supply, the body of NMOS B 712 may be coupled to ground 726, the source of NMOS B 712 may be coupled to inverter A 716 and the gate of NMOS B 712 may be coupled to the latch 722 (and to the output node 724).

In the configuration illustrated in FIG. 8, inverter A 716 includes p-channel metal-oxide semiconductor field-effect transistor (PMOS) A 728 and NMOS A 730. Inverter A 716 may be coupled to the second power supply, to NMOS B 712, to the latch 722 (through a first node 720 or coupling) and to the hysteresis circuit 774 (e.g., NMOS C 770 and/or to NMOS D 772 through the first node 720). For example, the gate of PMOS A 728 may be coupled to the second power supply (that provides a second voltage 710), the source of PMOS A 728 may be coupled to the source of NMOS B 712, the body of PMOS A 728 may be coupled to the first power supply (that provides a first voltage 706) and the drain of PMOS A 728 may be coupled to NMOS A 730 and to the latch 722 (and/or to NMOS D 772 through the first node 720). The drain of NMOS A 730 may be coupled to the drain of PMOS A 728 and to the latch 722 (and/or to NMOS D 772 through the first node 720), the body of NMOS A 730 may be coupled to ground 726, the source of NMOS A 730 may be coupled to the hysteresis circuit 774 (e.g., NMOS C 770 and NMOS D 772) and the gate of NMOS A 730 may be coupled to the second power supply (that provides a second voltage 710), to the gate of PMOS A 728 and/or to the hysteresis circuit 774 (e.g., NMOS C 770).

In one configuration, the hysteresis circuit 774 may include NMOS C 770 and NMOS D 772. For example, NMOS C 770 may be coupled to inverter A 716, to NMOS D 772 and to ground 726. More specifically, the drain of NMOS C 770 may be coupled to the source of NMOS A 730 and/or to NMOS D 772, the body of NMOS C 770 may be coupled to ground 726, the source of NMOS C 770 may be coupled to ground 726 and the gate of NMOS C 770 may be coupled to the second power supply (that provides a second voltage 710), to the gate of PMOS A 728 and/or to the gate of NMOS A 730.

In the configuration illustrated in FIG. 8, the latch 722 includes PMOS B 732 and inverter B 734. The latch 722 may be coupled to NMOS B 712, to inverter A 716 (through a first node 720) and to the hysteresis circuit 774 (e.g., NMOS D 772 through the first node 720). More specifically, the gate of PMOS B 732 may be coupled to the gate of NMOS B 712 and the output node 724, the source of PMOS B 732 may be coupled to the first power supply (that provides a first voltage 706), the body of PMOS B 732 may be coupled to the first power supply (that provides the first voltage 706), the drain of PMOS B 732 may be coupled to the drain of PMOS A 728, to the drain of NMOS A 730, to inverter B 734 and/or to the hysteresis circuit 774 (e.g., NMOS D 772). The input to inverter B 734 may be coupled to the drain of PMOS A 728, to the drain of NMOS A 730, to the drain of PMOS B 732 and/or to the hysteresis circuit 774 (e.g., NMOS D 772). Inverter B 734 may be coupled to the first supply (that provides the first voltage 706). The output of inverter B 734 may be coupled to the gate of NMOS B 712 and to the gate of PMOS B 732 and may provide the output signal at the output node 724. In some configurations, the latch 722 (e.g., output node 724) may be coupled to another circuit or electronic device. For example, the latch 722 may be coupled to one or more level shifter circuits.

In one configuration, NMOS D 772 in the hysteresis circuit 774 may be coupled to inverter A 716, to the latch 722, to NMOS C 770, to the first power supply (that supplies the first voltage 706) and to ground 726. More specifically, the drain of NMOS D 772 may be coupled to the first power supply, the body of NMOS D 772 may be coupled to ground 726, the source of NMOS D 772 may be coupled to the source of NMOS A 730 and to the drain of NMOS C 770 and the gate of NMOS D 772 may be coupled to the drain of PMOS A 728, to the drain of NMOS A 730, to the drain of PMOS B 732 and to the input to inverter B 734.

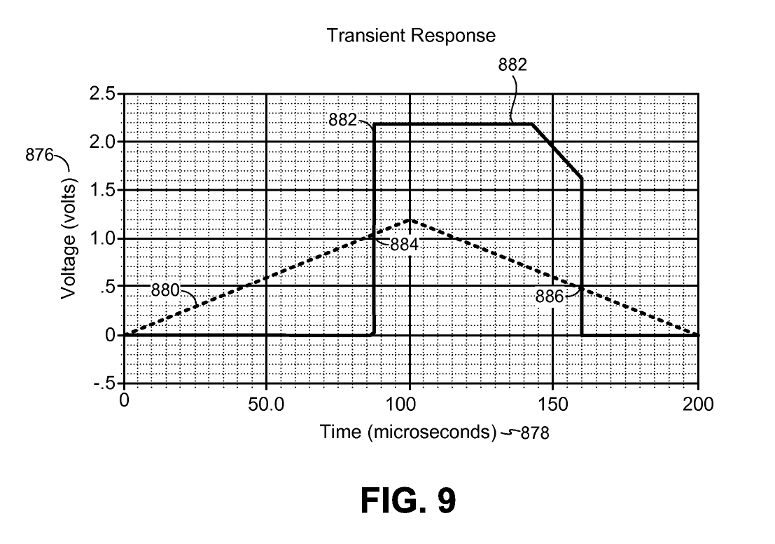

As described above, the hysteresis circuit 774 may include NMOS C 770 and NMOS D 772. The hysteresis circuit 774 may be added to the supply collapse detection circuit 702 (e.g., to NMOS A 730) in order to change a low-to-high threshold of the supply collapse detection circuit 702. FIG. 9 illustrates one example of the how the threshold for the supply collapse detection circuit 702 can change by adding the hysteresis circuit 774.

FIG. 9 is a graph illustrating an example of a transient response of a supply collapse detection circuit 702 with an added hysteresis circuit 774. The graph illustrates an input voltage 880 (e.g., a second voltage 710) and an output voltage or signal 882 (e.g., an output signal at the output node 724). The input voltage 880 and the output voltage or signal 882 are illustrated in volts 876 along the vertical axis and in time (nanoseconds) 878 along the horizontal axis.

As described above, adding a hysteresis circuit 774 to the supply collapse detection circuit 702 may change or move the threshold points in the transient response. For a supply collapse detection circuit 202 without a hysteresis circuit 774, for example, a first crossing point in a hysteresis sweep (from low to high) between an input voltage and an output voltage occurred at approximately 645.8 mV and 2.691 μs and a second crossing point (from high to low) occurred at approximately 306.4 mV and 8.723 μs as discussed above. However, for a supply collapse detection circuit 702 with a hysteresis circuit 774, for example, a first crossing point 884 in a hysteresis sweep (from low to high) between an input voltage and an output voltage occurred at approximately 1.073 V and 87.38 μs and the second crossing point 886 (from high to low) occurred at approximately 487.7 mV and 159.4 μs.

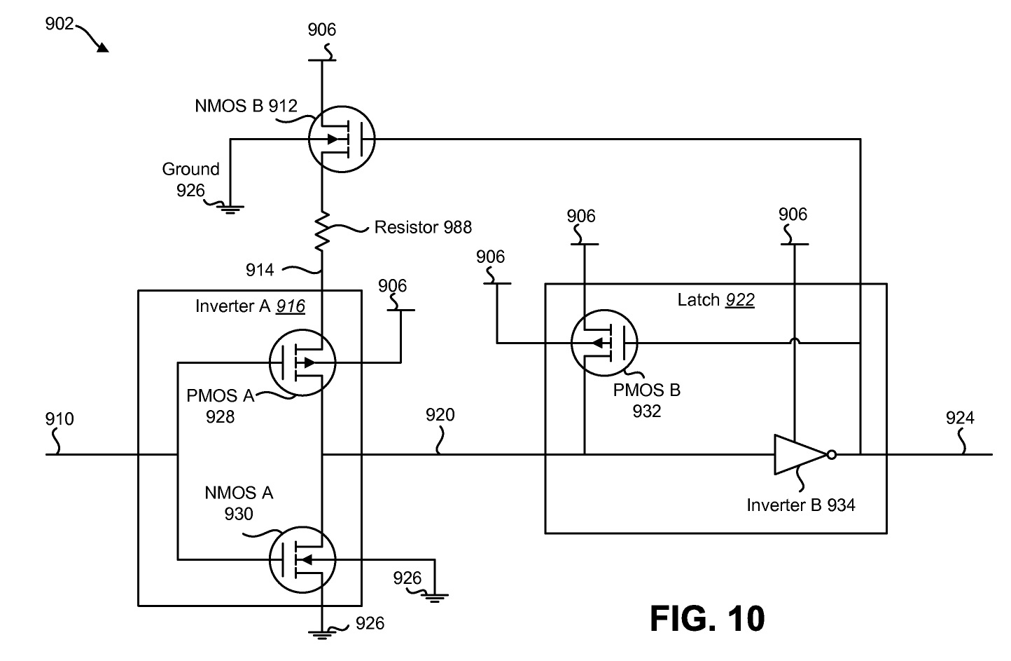

FIG. 10 is a block diagram illustrating another more specific configuration of a supply collapse detection circuit 902. The supply collapse detection circuit 902 may be coupled to a first power supply that supplies a first voltage 906 and a second power supply that supplies a second voltage 910. More specifically, the first power supply supplies a first voltage 906 and the second power supply supplies a second voltage 910 to the supply collapse detection circuit 902. The supply collapse detection circuit 902 may also be coupled to ground 926. The ground 926 may be a reference point in relation to which electrical potential (e.g., voltages 906, 910) may exist. Additionally or alternatively, ground 926 may provide a common return path for electrical charge in a circuit (e.g., the supply collapse detection circuit 902).

In one configuration, the first voltage 906 may be higher than the second voltage 910. For example, the first power supply may be a power supply circuit that provides a (first) voltage 906 to analog components or circuits of a device (e.g., electronic device, circuit, chip, etc.) that require a higher voltage to function. For instance, the first voltage 906 provided by the first power supply may be 1.8V or 2V. In some cases, the first power supply may be referred to as an “analog supply.”

The second power supply may be a power supply that provides a (second) voltage 910 to digital components or circuits of a device (e.g., electronic device, circuit, chip, etc.) that require a lower voltage to function. In some cases, the second power supply may be referred to as a “digital supply.” For instance, the second voltage 910 provided by the second power supply may be 1.2V. In some configurations, the first power supply and the second power supply may provide voltages 906, 910 from the same power source, such as a battery and/or a power outlet.

The supply collapse detection circuit 902 may provide an output signal (e.g., a freeze signal) at an output node 924 that indicates when the second power supply or the second voltage 910 has collapsed. For example, the second power supply may be cut off from providing the second voltage 910 to the supply collapse detection circuit 902 and/or other circuits. Thus, for example, the second voltage 910 may drop or be diminished. The supply collapse detection circuit 902 may detect when this collapse has occurred and provide the output signal (at the output node 924) indicating that the collapse has occurred.

In one configuration, the output signal may be provided to one or more level shifter circuits from the output node 924. In one example, the supply collapse detection circuit 902 may be included in an electronic device (e.g., cell phone) that uses analog and digital components. In order to conserve energy (e.g., battery charge), the electronic device may cut off power to one or more digital circuits such as level shifter circuits, thereby placing them into a sleep mode. However, if the digital supply (e.g., the second power supply) is cut off while the analog supply (e.g., the first power supply) is provided, the digital circuit(s) may be placed in a floating state and heavy leakage (e.g., current leakage) from the digital circuits (e.g., level shifter circuits) may occur. In order to reduce leakage, the output signal (from the output node 924) may be provided to the digital circuit(s), which may place the digital circuit(s) in a frozen state, thereby reducing leakage.

The supply collapse detection circuit 902 may include N-channel metal-oxide semiconductor field-effect transistor (NMOS) B 912, a resistor 988, inverter A 916 and a latch 922. NMOS B 912 may be one example of the feedback circuitry 112 illustrated in FIG. 2. Inverter A 916 may be one example of the threshold detection circuitry 116 illustrated in FIG. 2. The latch 922 may be one example of the supply collapse output circuitry 122 illustrated in FIG. 2. The first power supply may provide the first voltage 906 to NMOS B 912, inverter A 916 and the latch 922. The second power supply may provide the second voltage 910 to inverter A 916. NMOS B 912, inverter A 916 and the latch 922 may be coupled to ground 926.

NMOS B 912 may be coupled to the first power supply (that supplies a first voltage 906), to the resistor 988, to the latch 922 and to ground 926. More specifically, the drain of NMOS B 912 may be coupled to the first power supply, the body of NMOS B 912 may be coupled to ground 926, the source of NMOS B 912 may be coupled to the resistor 988 and the gate of NMOS B 912 may be coupled to the latch 922 (and to the output node 924).

In the configuration illustrated in FIG. 10, the resistor 988 is coupled to the source of NMOS B 912 and to inverter A 916 (through a second node or coupling 914). The resistor 988 may be added to the supply collapse detection circuit 902 in order to further reduce leakage.

In the configuration illustrated in FIG. 10, inverter A 916 includes p-channel metal-oxide semiconductor field-effect transistor (PMOS) A 928 and NMOS A 930. Inverter A 916 may be coupled to the second power supply, to the resistor 988 (through the second node 914), to the latch 922 (through a first node 920 or coupling) and to ground 926. More specifically, the gate of PMOS A 928 may be coupled to the second power supply (that provides a second voltage 910), the source of PMOS A 928 may be coupled to the resistor 988, the body of PMOS A 928 may be coupled to the first power supply (that provides a first voltage 906) and the drain of PMOS A 928 may be coupled to NMOS A 930 and to the latch 922. The drain of NMOS A 930 may be coupled to the drain of PMOS A 928 and to the latch 922, the body of NMOS A 930 may be coupled to ground 926, the source of NMOS A 930 may be coupled to ground 926 and the gate of NMOS A 930 may be coupled to the second power supply (that provides a second voltage 910) and/or to the gate of PMOS A 928.

In the configuration illustrated in FIG. 10, the latch 922 includes PMOS B 932 and inverter B 934. The latch 922 may be coupled to NMOS B 912 and to inverter A 916 (through a first node 920). More specifically, the gate of PMOS B 932 may be coupled to the gate of NMOS B 912 and to the output node 924, the source of PMOS B 932 may be coupled to the first power supply (that provides a first voltage 906), the body of PMOS B 932 may be coupled to the first power supply (that provides the first voltage 906), the drain of PMOS B 932 may be coupled to the drain of PMOS A 928, to the drain of NMOS A 930 and to inverter B 934. The input to inverter B 934 may be coupled to the drain of PMOS A 928, to the drain of NMOS A 930 and to the drain of PMOS B 932. Inverter B 934 may be coupled to the first supply (that provides the first voltage 906). The output of inverter B 934 may be coupled to the gate of NMOS B 912 and to the gate of PMOS B 932 and may provide the output signal at the output node 924. In some configurations, the latch 922 (e.g., output node 924) may be coupled to another circuit or electronic device. For example, the latch 922 may be coupled to one or more level shifter circuits.

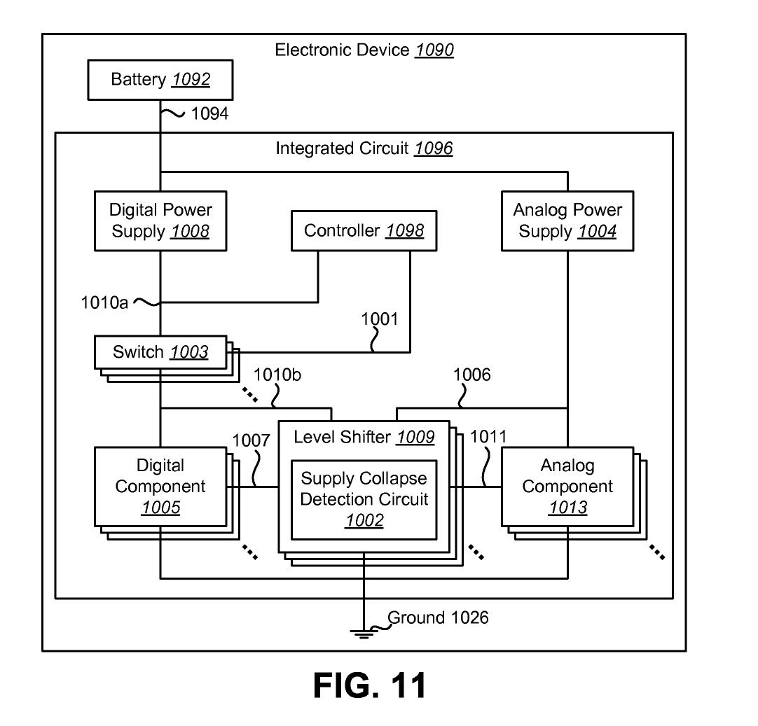

FIG. 11 is a block diagram illustrating one configuration of an electronic device 1090 in which one or more supply collapse detection circuits 1002 may be implemented. Examples of the electronic device 1090 include cellular phones, smartphones, music players, audio recorders, digital cameras, laptop computers, desktop computers, personal digital assistants (PDAs), etc. The electronic device 1090 may include a battery 1092 and an integrated circuit 1096. The integrated circuit 1096 may be coupled to the battery 1092 and to ground 1026. The battery 1092 may supply a voltage 1094 to the integrated circuit 1096 (e.g., to a digital power supply 1008 and to an analog power supply 1004).

The integrated circuit 1096 may include a digital power supply 1008, an analog power supply 1004, a controller 1098, one or more switches 1003, one or more digital components 1005, one or more level shifters 1009 and/or one or more analog components 1013. The analog power supply 1004 may be a circuit that supplies a first voltage 1006 to the one or more analog components 1013 and to the one or more level shifters 1009. The digital power supply 1008 may be a circuit that supplies a voltage 1010 to the one or more digital components 1005 as well as the one or more level shifters 1009. The first voltage 1006 supplied by the analog power supply 1004 may be higher in voltage than the second voltage 1010 provided by the digital power supply 1008. The one or more digital components 1005, the one or more level shifters 1009 and the one or more analog components 1013 may be coupled to ground 1026.

It should be noted that a level shifter circuit 1009 may be a circuit that changes the level (e.g., amplitude) of signals between circuits or components. For example, a digital component or circuit 1005 may output a signal 1007 with a lower amplitude than is needed to drive an analog component or circuit 1013. A level-up shifter 1009 may shift or raise the digital component output signal 1007 amplitude up to produce a signal 1011 with a level used by the analog component 1013, for instance.

The controller 1098 may be a circuit (e.g., processor) that controls the integrated circuit and/or performs one or more functions for the electronic device 1090. For example, the controller 1098 may be a mobile station modem (MSM). The controller 1098 may monitor the usage of the one or more digital components 1005. The controller 1098 may determine to cut off the one or more digital components 1005 from the digital power supply 1008. The controller 1098 may produce a control signal 1001 used to control the one or more switches 1003. The controller 1098 may cut off the digital power supply voltage 1010a using the one or more switches 1003. This may be done to place one or more digital components 1005 in a sleep mode in order to preserve battery 1092 charge. When the controller 1098 cuts off the digital power supply 1008 (second) voltage 1010a using the one or more switches 1003, the second voltage 1010b to the one or more digital components 1005 and to the one or more level shifters 1009 may drop or collapse. It should be noted that the voltage 1010b may be selectively cut off only to selected digital components 1005.

The one or more level shifters 1009 may each include a supply collapse detection circuit 1002. When the second voltage 1010b drops or collapses (to all of the level shifters 1009 or to one or more selected level shifters 1009), each supply collapse detection circuit 1002 corresponding to a level shifter 1009 with a voltage 1010b drop may detect this drop and provide a freeze signal to the corresponding level shifter 1009. The corresponding level shifter(s) 1009 may then be placed in a frozen state in order to reduce or avoid leakage.

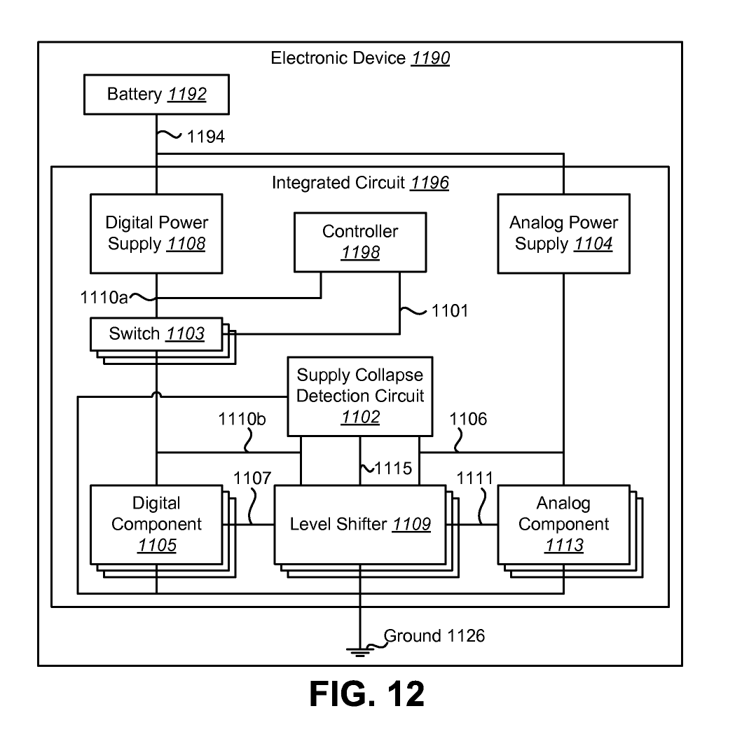

FIG. 12 is a block diagram illustrating one configuration of an electronic device 1190 in which a supply collapse detection circuit 1102 may be implemented. Examples of the electronic device 1190 include cellular phones, smartphones, music players, audio recorders, digital cameras, laptop computers, desktop computers, personal digital assistants (PDAs), etc. The electronic device 1190 may include a battery 1192 and an integrated circuit 1196. The integrated circuit 1196 may be coupled to the battery 1192 and to ground 1126. The battery 1192 may supply a voltage 1194 to the integrated circuit 1196 (e.g., to a digital power supply 1108 and to an analog power supply 1104).

The integrated circuit 1196 may include a digital power supply 1108, an analog power supply 1104, a controller 1198, one or more switches 1103, a supply collapse detection circuit 1102, one or more digital components 1105, one or more level shifters 1109 and/or one or more analog components 1113. The analog power supply 1104 may be a circuit that supplies a first voltage 1106 to the one or more analog components 1113, to the supply collapse detection circuit 1102 and to the one or more level shifters 1109. The digital power supply 1108 may be a circuit that supplies a voltage 1110 to the one or more digital components 1105, to the supply collapse detection circuit 1102 and to the one or more level shifters 1109. The first voltage 1106 supplied by the analog power supply 1104 may be higher in voltage than the second voltage 1110 provided by the digital power supply 1108. The one or more digital components 1105, the supply collapse detection circuit 1102, the one or more level shifters 1109 and the one or more analog components 1113 may be coupled to ground 1126.

It should be noted that a level shifter circuit 1109 may be a circuit that changes the level (e.g., amplitude) of signals between circuits or components. For example, a digital component or circuit 1105 may output a signal 1107 with a lower amplitude than is needed to drive an analog component or circuit 1113. A level-up shifter 1109 may shift or raise the digital component output signal 1107 amplitude up to produce a signal 1111 with a level used by the analog component 1113, for instance.

The controller 1198 may be a circuit (e.g., processor) that controls the integrated circuit 1196 and/or performs one or more functions for the electronic device 1190. For example, the controller 1198 may be a mobile station modem (MSM). The controller 1198 may monitor the usage of the one or more digital components 1105. The controller 1198 may determine to cut off the one or more digital components 1105 from the digital power supply 1108. The controller 1198 may produce a control signal 1101 used to control the one or more switches 1103. The controller 1198 may cut off the digital power supply voltage 1110a using the one or more switches 1103. This may be done to place one or more digital components 1105 in a sleep mode in order to preserve battery 1192 charge. When the controller 1198 cuts off the digital power supply 1108 (second) voltage 1110a using the one or more switches 1103, the second voltage 1110b to the supply collapse detection circuit 1102, to the one or more digital components 1105 and to the one or more level shifters 1109 may drop or collapse. It should be noted that the voltage 1110b may be selectively cut off only to selected digital components 1105.

When the second voltage 1110b drops or collapses (to all of the level shifters 1109 or to one or more selected level shifters 1109), the supply collapse detection circuit 1102 may detect this drop and provide a freeze signal 1115 to each level shifter 1109 experiencing a voltage 1110b drop or collapse. The corresponding level shifter(s) 1109 may then be placed in a frozen state in order to reduce or avoid leakage.

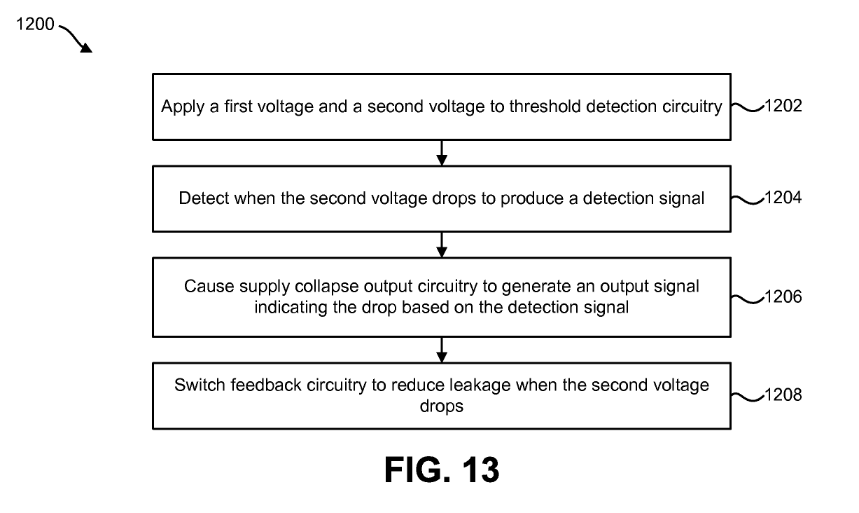

FIG. 13 is a flow diagram illustrating one configuration of a method 1200 for providing a power supply collapse signal. A supply collapse detection circuit 102 may apply 1202 a first voltage 106 and a second voltage 110 to threshold detection circuitry 116. For example, the threshold detection circuitry 116 may have a first voltage 106 applied to it from power supply A 104 and may have a second voltage 110 applied to it from power supply B 108.

The supply collapse detection circuit 102 may detect 1204 when the second voltage 110 drops to produce a detection signal. For example, when the second voltage 110 drops (e.g., is reduced at all or is reduced by a threshold amount), the threshold detection circuitry 116 may produce a detection signal (at a first node 120, for example) that indicates a drop or collapse in the second voltage 110.

The supply collapse detection circuit 102 may cause 1206 supply collapse output circuitry 122 to generate an output signal (at the output node 124, for example) indicating the drop based on the detection signal. For example, the supply collapse output circuitry 122 may generate an output signal indicating the drop in the second voltage 110 when the detection signal indicates that the second voltage 110 has dropped.

The supply collapse detection circuit 102 may switch 1208 the feedback circuitry 112 to reduce leakage when the second voltage 110 drops. For example, the output signal may be provided to the feedback circuitry 112, which may switch 1208 to reduce leakage when the second voltage 110 drops.

In one configuration of the systems and methods disclosed herein, the method 1200 may be performed with a controller or processor and instructions. For example, a processor may apply 1202 the first voltage and second voltage to threshold detection circuitry by controlling one or more switches. The processor may detect 1204 when the second voltage drops by receiving a signal from threshold detection circuitry and may then produce or route the detection signal. The processor may also cause 1206 supply output circuitry to generate an output signal indicating the drop based on the detection signal. For example, the processor may send a control signal to supply output collapse circuitry that causes it to generate the output signal. Additionally, the processor may switch 1208 feedback circuitry to reduce leakage when the second voltage drops. For example, the processor may send a control signal to the feedback circuitry that causes it to switch. In other configurations of the systems and methods disclosed herein, the method 1200 may be performed without the use of a processor and instructions.

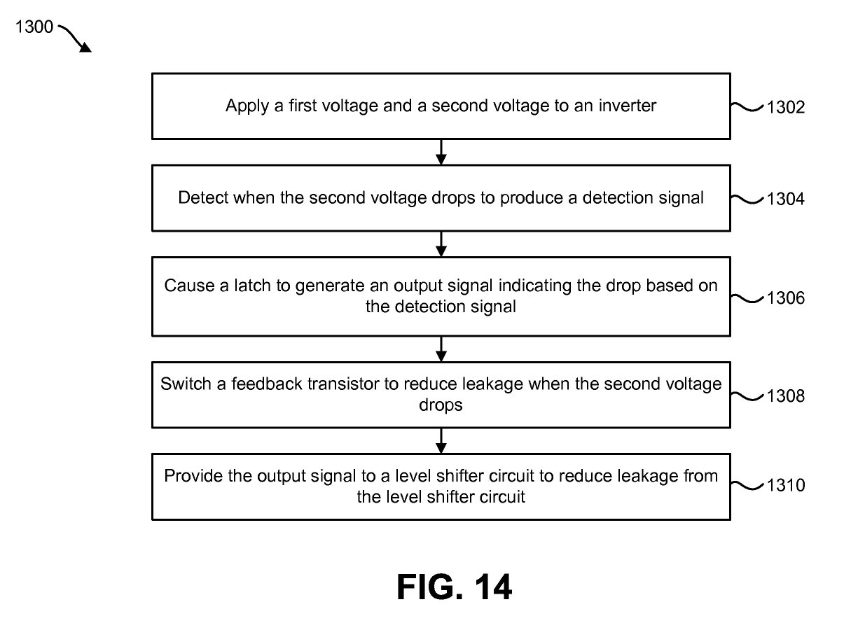

FIG. 14 is a flow diagram illustrating a more specific configuration of a method 1300 for providing a power supply collapse signal. A supply collapse detection circuit 202 may apply 1302 a first voltage 206 and a second voltage 210 to an inverter 216. For example, inverter A 216 may have a first voltage 206 applied to it from a first power supply (to PMOS A 228, for example) and may have a second voltage 210 applied to it from a second power supply (to PMOS A 228 and to NMOS A 230, for example).

The supply collapse detection circuit 202 may detect 1304 when the second voltage 210 drops to produce a detection signal. For example, when the second voltage 210 drops (e.g., is reduced at all or is reduced by a threshold amount), inverter A 216 may produce a detection signal (at a first node 220, for example) that indicates a drop or collapse in the second voltage 210. For instance, when the second voltage 210 drops a particular amount (e.g., a threshold amount), PMOS A 228 may be “turned on,” thereby allowing the voltage at the second node 214 (e.g., node z) to charge the first node 220 (e.g., node x). The first node 220 may be charged up to the first voltage 206 in one configuration.

The supply collapse detection circuit 202 may cause 1306 the latch 222 to generate an output signal (at the output node 224, for example) indicating the drop based on the detection signal. For example, the latch 222 may generate an output signal at the output node 224 indicating the drop in the second voltage 210 when the detection signal indicates that the second voltage 210 has dropped. For instance, when the voltage at the first node 220 (e.g., node x) increases a certain amount, the latch 222 trips, causing the voltage at the output node 224 (e.g., node y) to be pulled to zero.

The supply collapse detection circuit 202 may switch 1308 a feedback transistor 212 to reduce leakage when the second voltage drops. For example, the output signal (at the output node 224, for example) may be provided to NMOS B 212 that may switch in order to reduce leakage when the second voltage 210 drops.

The supply collapse detection circuit 202 may provide 1310 the output signal to a level shifter circuit to reduce leakage from the level shifter circuit. For example, a freeze signal at the output node 224 may be indicated when the voltage at the output node 224 drops to zero. This output signal or freeze signal may be provided to one or more level shifter circuits (e.g., level shifter 1009, 1109). The freeze signal may cause the level shifters to enter a frozen state, thereby reducing leakage (and/or avoiding a floating state).

In one configuration of the systems and methods disclosed herein, the method 1300 may be performed with a controller or processor and instructions. For example, a processor may apply 1302 the first voltage and second voltage to an inverter by controlling one or more switches. The processor may detect 1304 when the second voltage drops by receiving a signal from the inverter and may then produce or route the detection signal. The processor may also cause 1306 a latch to generate an output signal indicating the drop based on the detection signal. For example, the processor may send a control signal to supply output collapse circuitry that causes it to generate the output signal. Additionally, the processor may switch 1308 a feedback transistor to reduce leakage when the second voltage drops. For example, the processor may send a control signal to the feedback transistor that causes it to switch. The processor may also provide the output signal to a level shifter circuit to reduce leakage from the level shifter circuit. For example, the processor may route or direct the output signal to a level shifter circuit. In other configurations of the systems and methods disclosed herein, the method 1300 may be performed without the use of a processor and instructions.

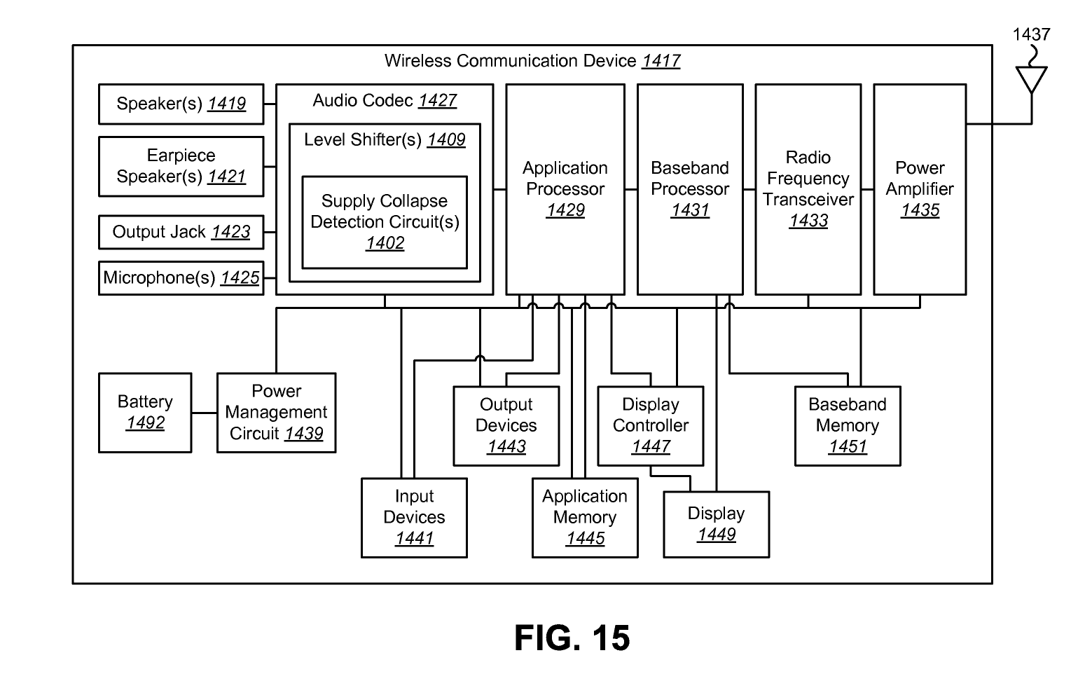

FIG. 15 is a block diagram illustrating one configuration of several components in a wireless communication device 1417 in which one or more supply collapse detection circuits 1402 may be implemented. The wireless communication device 1417 may include an application processor 1429. The application processor 1429 generally processes instructions (e.g., runs programs) to perform functions on the wireless communication device 1417. The application processor 1429 may be coupled to an audio coder/decoder (codec) 1427.

The audio codec 1427 may be an electronic device (e.g., integrated circuit) used for coding and/or decoding audio signals. The audio codec 1427 may be coupled to one or more speakers 1419, one or more earpiece speakers 1421, an output jack 1423 and/or one or more microphones 1425. The speakers 1419 may include one or more electro-acoustic transducers that convert electrical or electronic signals into acoustic signals. For example, the speakers 1419 may be used to play music or output a speakerphone conversation, etc. The one or more earpiece speakers 1421 may include one or more speakers or electro-acoustic transducers that can be used to output acoustic signals (e.g., speech signals) to a user. For example, one or more earpiece speakers 1421 may be used such that only a user may reliably hear the acoustic signal. The output jack 1423 may be used for coupling other devices to the wireless communication device 1417 for outputting audio, such as headphones. The speakers 1419, one or more earpiece speakers 1421 and/or output jack 1423 may generally be used for outputting an audio signal from the audio codec. The one or more microphones 1425 may be acousto-electric transducers that convert an acoustic signal (such as a user's voice) into electrical or electronic signals that are provided to the audio codec 1427.

The audio codec 1427 may include one or more level shifters 1409. The level shifter(s) 1409 may be one example of one or more of the level shifters 1009, 1109 described in FIGS. 11-12 above or other level shifters described above. In one example of the systems and methods disclosed herein, the level shifter(s) 1409 may be used to shift up a digital audio signal to a digital-to-analog converter for output to speaker(s) 1419, earpiece speaker(s) 1421 and/or the output jack 1423. The one or more level shifters 1409 may include one or more supply collapse detection circuits 1402. Alternatively, the one or more supply collapse detection circuits 1402 may be separate from the one or more level shifters 1409. For example, the one or more supply collapse detection circuits 1402 may be located in the audio codec 1427 separately from the one or more level shifters 1409. The supply collapse detection circuits 1402 may be one example of one or more of the supply collapse detection circuits 102, 202, 502, 702, 902, 1002, 1102 described above.

The application processor 1429 may be coupled to the power management circuit 1439. One example of a power management circuit 1439 is a power management integrated circuit (PMIC), which may be used to manage the electrical power consumption of the wireless communication device 1417. The power management circuit 1439 may be coupled to a battery 1492. The battery 1492 may generally provide electrical power to the wireless communication device 1417. The battery 1492 and/or the power management circuit 1439 may be additionally or alternatively coupled to the audio codec 1427, baseband processor 1431, to the radio frequency transceiver 1433, to the power amplifier 1435, to one or more input devices 1441, to one or more output devices 1443, to application memory 1445, to a display controller 1447, to a display 1449 and/or to baseband memory 1451.

The application processor 1429 may be coupled to one or more input devices 1441 for receiving input. Examples of input devices 1441 include infrared sensors, image sensors, accelerometers, touch sensors, keypads, etc. The input devices 1441 may allow user interaction with the wireless communication device 1417. The application processor 1429 may also be coupled to one or more output devices 1443. Examples of output devices 1443 include printers, projectors, screens, haptic devices, etc. The output devices 1443 may allow the wireless communication device 1417 to produce output that may be experienced by a user.

The application processor 1429 may be coupled to application memory 1445. The application memory 1445 may be any electronic device that is capable of storing electronic information. Examples of application memory 1445 include double data rate synchronous dynamic random access memory (DDRAM), synchronous dynamic random access memory (SDRAM), flash memory, etc. The application memory 1445 may provide storage for the application processor 1429. For instance, the application memory 1445 may store data and/or instructions for the functioning of programs that are run on the application processor 1429.

The application processor 1429 may be coupled to a display controller 1447, which in turn may be coupled to a display 1449. The display controller 1447 may be a hardware block that is used to generate images on the display 1449. For example, the display controller 1447 may translate instructions and/or data from the application processor 1429 into images that can be presented on the display 1449. Examples of the display 1449 include liquid crystal display (LCD) panels, light emitting diode (LED) panels, cathode ray tube (CRT) displays, plasma displays, etc.

The application processor 1429 may be coupled to a baseband processor 1431. The baseband processor 1431 generally processes communication signals. For example, the baseband processor 1431 may demodulate and/or decode received signals. Additionally or alternatively, the baseband processor 1431 may encode and/or modulate signals in preparation for transmission.

The baseband processor 1431 may be coupled to baseband memory 1451. The baseband memory 1451 may be any electronic device capable of storing electronic information, such as SDRAM, DDRAM, flash memory, etc. The baseband processor 1431 may read information (e.g., instructions and/or data) from and/or write information to the baseband memory 1451. Additionally or alternatively, the baseband processor 1431 may use instructions and/or data stored in the baseband memory 1451 to perform communication operations.

The baseband processor 1431 may be coupled to a radio frequency (RF) transceiver 1433. The RF transceiver 1433 may be coupled to a power amplifier 1435 and one or more antennas 1437. The RF transceiver 1433 may transmit and/or receive radio frequency signals. For example, the RF transceiver 1433 may transmit an RF signal using a power amplifier 1435 and one or more antennas 1437. The RF transceiver 1433 may also receive RF signals using the one or more antennas 1437.

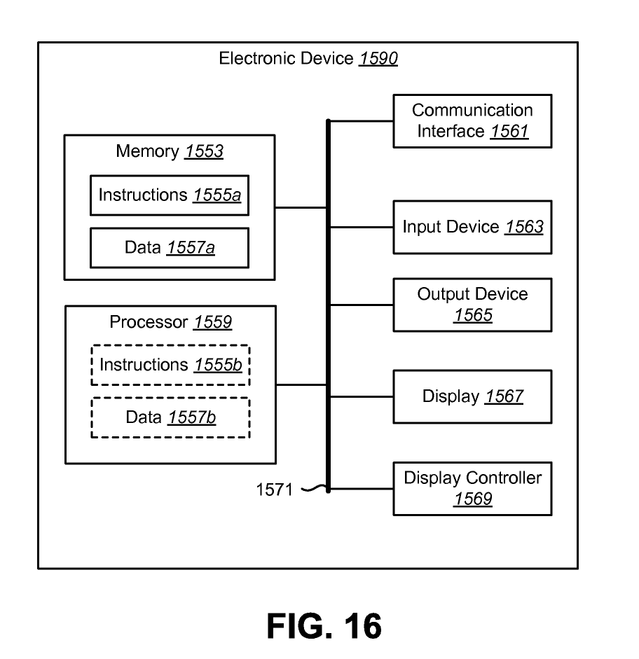

FIG. 16 illustrates various components that may be utilized in an electronic device 1590. The illustrated components may be located within the same physical structure or in separate housings or structures. The electronic devices 1090, 1190 discussed in relation to FIGS. 11 and 12 and/or the wireless communication device 1417 discussed in connection with FIG. 15 may be configured similarly to the electronic device 1590. The electronic device 1590 includes a processor 1559. The processor 1559 may be a general purpose single- or multi-chip microprocessor (e.g., an ARM), a special purpose microprocessor (e.g., a digital signal processor (DSP)), a microcontroller, a programmable gate array, etc. The processor 1559 may be referred to as a central processing unit (CPU). Although just a single processor 1559 is shown in the electronic device 1590 of FIG. 16, in an alternative configuration, a combination of processors (e.g., an ARM and DSP) could be used.

The electronic device 1590 also includes memory 1553 in electronic communication with the processor 1559. That is, the processor 1559 can read information from and/or write information to the memory 1553. The memory 1553 may be any electronic component capable of storing electronic information. The memory 1553 may be random access memory (RAM), read-only memory (ROM), magnetic disk storage media, optical storage media, flash memory devices in RAM, on-board memory included with the processor, programmable read-only memory (PROM), erasable programmable read-only memory (EPROM), electrically erasable PROM (EEPROM), registers, and so forth, including combinations thereof.

Data 1557a and instructions 1555a may be stored in the memory 1553. The instructions 1555a may include one or more programs, routines, sub-routines, functions, procedures, etc. The instructions 1555a may include a single computer-readable statement or many computer-readable statements. The instructions 1555a may be executable by the processor 1559 to implement the methods 1200, 1300 described herein. Executing the instructions 1555a may involve the use of the data 1557a that is stored in the memory 1553. FIG. 16 shows some instructions 1555b and data 1557b being loaded into the processor 1559.

The electronic device 1590 may also include one or more communication interfaces 1561 for communicating with other electronic devices. The communication interfaces 1561 may be based on wired communication technology, wireless communication technology, or both. Examples of different types of communication interfaces 1561 include a serial port, a parallel port, a Universal Serial Bus (USB), an Ethernet adapter, an IEEE 1394 bus interface, a small computer system interface (SCSI) bus interface, an infrared (IR) communication port, a Bluetooth wireless communication adapter, and so forth.

The electronic device 1590 may also include one or more input devices 1563 and one or more output devices 1565. Examples of different kinds of input devices 1563 include a keyboard, mouse, microphone, remote control device, button, joystick, trackball, touchpad, lightpen, touchscreen, etc. Examples of different kinds of output devices 1565 include a speaker, printer, etc. One specific type of output device that may be typically included in an electronic device 1590 is a display device 1567. Display devices 1567 used with configurations disclosed herein may utilize any suitable image projection technology, such as a cathode ray tube (CRT), liquid crystal display (LCD), light-emitting diode (LED), gas plasma, electroluminescence, or the like. A display controller 1569 may also be provided for converting data stored in the memory 1553 into text, graphics, and/or moving images (as appropriate) shown on the display device 1567.

The various components of the electronic device 1590 may be coupled together by one or more buses, which may include a power bus, a control signal bus, a status signal bus, a data bus, etc. For simplicity, the various buses are illustrated in FIG. 16 as a bus system 1571. It should be noted that FIG. 16 illustrates only one possible configuration of an electronic device 1590. Various other architectures and components may be utilized.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The term “processor” should be interpreted broadly to encompass a general purpose processor, a central processing unit (CPU), a microprocessor, a digital signal processor (DSP), a controller, a microcontroller, a state machine, and so forth. Under some circumstances, a “processor” may refer to an application specific integrated circuit (ASIC), a programmable logic device (PLD), a field programmable gate array (FPGA), etc. The term “processor” may refer to a combination of processing devices, e.g., a combination of a DSP and a microprocessor, a plurality of microprocessors, one or more microprocessors in conjunction with a DSP core, or any other such configuration.

The term “memory” should be interpreted broadly to encompass any electronic component capable of storing electronic information. The term memory may refer to various types of computer-readable or processor-readable media such as random access memory (RAM), read-only memory (ROM), non-volatile random access memory (NVRAM), programmable read-only memory (PROM), erasable programmable read-only memory (EPROM), electrically erasable PROM (EEPROM), flash memory, magnetic or optical data storage, registers, etc. Memory is said to be in electronic communication with a processor if the processor can read information from and/or write information to the memory. Memory that is integral to a processor is in electronic communication with the processor.

The terms “instructions” and “code” should be interpreted broadly to include any type of processor-readable or computer-readable statement(s). For example, the terms “instructions” and “code” may refer to one or more programs, routines, sub-routines, functions, procedures, etc. “Instructions” and “code” may comprise a single computer-readable statement or many computer-readable statements.

The functions described herein may be implemented in hardware, software, firmware, or any combination thereof. If implemented in software, the functions may be stored as one or more instructions on a processor-readable or computer-readable medium. The terms “computer-readable medium,” “computer-program product” or “processor-readable medium” refers to any available medium that can be accessed by a computer or processor. By way of example, and not limitation, such a medium may comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

Further, it should be appreciated that modules and/or other appropriate means for performing the methods and techniques described herein, such as those illustrated by FIGS. 13 and 14, can be downloaded and/or otherwise obtained by a device. For example, a device may be coupled to a server to facilitate the transfer of means for performing the methods described herein. Alternatively, various methods described herein can be provided via a storage means (e.g., random access memory (RAM), read-only memory (ROM), a physical storage medium such as a compact disc (CD) or floppy disk, etc.), such that a device may obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. A supply collapse detection circuit, comprising:
threshold detection circuitry coupled to a first power supply and to a second power supply that provides a second voltage;
supply collapse output circuitry coupled to the threshold detection circuitry to receive a detection signal when the second voltage drops, wherein the supply collapse output circuitry comprises an output node to provide an output signal indicating the drop; and
feedback circuitry coupled to the first power supply, to the threshold detection circuitry and to the supply collapse output circuitry, wherein the feedback circuitry reduces leakage when the second voltage drops.

2. The supply collapse detection circuit of claim 1, wherein the output node is coupled to a level shifter circuit.

3. The supply collapse detection circuit of claim 2, wherein the output signal is provided to the level shifter circuit to reduce leakage from the level shifter circuit.

4. The supply collapse detection circuit of claim 1, wherein the threshold detection circuitry comprises an inverter circuit.

5. The supply collapse detection circuit of claim 4, wherein the inverter circuit comprises:
a P-channel metal-oxide-semiconductor field-effect-transistor (PMOS), wherein a gate of the PMOS is coupled to the second power supply, a source of the PMOS is coupled to the feedback circuitry, a body of the PMOS is coupled to the first power supply and a drain of the PMOS is coupled to the supply collapse output circuitry; and
an N-channel metal-oxide-semiconductor field-effect transistor (NMOS), wherein a gate of the NMOS is coupled to the second power supply and to the gate of the PMOS, a source of the NMOS is coupled to a ground, a body of the NMOS is coupled to the ground and a drain of the NMOS is coupled to the supply collapse output circuitry and to the drain of the PMOS.

6. The supply collapse detection circuit of claim 1, wherein the feedback circuitry comprises a feedback transistor.

7. The supply collapse detection circuit of claim 6, wherein the feedback transistor comprises an N-channel metal-oxide-semiconductor field-effect transistor (NMOS), wherein a gate of the NMOS is coupled to the supply collapse output circuitry, a source of the NMOS is coupled to the threshold detection circuitry, a body of the NMOS is coupled to a ground and a drain of the NMOS is coupled to the first power supply.

8. The supply collapse detection circuit of claim 1, wherein the supply collapse output circuitry comprises a latch.

9. The supply collapse detection circuit of claim 8, wherein the latch comprises:
an inverter that is coupled to the first power supply; and
a P-channel metal-oxide-semiconductor field-effect-transistor (PMOS), wherein a gate of the PMOS is coupled to an output of the inverter, a source of the PMOS is coupled to the first power supply, a body of the PMOS is coupled to the first power supply and a drain of the PMOS is coupled to an input of the inverter.

10. The supply collapse detection circuit of claim 1, further comprising a capacitor.

11. The supply collapse detection circuit of claim 10, wherein the capacitor comprises a P-channel metal-oxide-semiconductor field-effect-transistor (PMOS), wherein a gate of the PMOS is coupled to a ground, a source of the PMOS is coupled to a drain of the PMOS, to the feedback circuitry and to the threshold detection circuitry.

12. The supply collapse detection circuit of claim 1, further comprising a hysteresis circuit.

13. The supply collapse detection circuit of claim 12, wherein the hysteresis circuit comprises:
a first N-channel metal-oxide-semiconductor field-effect transistor (NMOS), wherein a gate of the first NMOS is coupled to the second power supply and to the threshold detection circuitry, a source of the first NMOS is coupled to a ground, a body of the first NMOS is coupled to the ground and a drain of the first NMOS is coupled to the threshold detection circuitry; and
a second NMOS, wherein a gate of the second NMOS is coupled to the latch and to the threshold detection circuitry, a source of the second NMOS is coupled to the drain of the first NMOS, a body of the second NMOS is coupled to the ground and a drain of the NMOS is coupled to the first power supply.

14. The supply collapse detection circuit of claim 1, further comprising a resistor coupled between the feedback circuitry and the threshold detection circuitry.

15. The supply collapse detection circuit of claim 1, wherein the supply collapse detection circuit is an integrated circuit.

16. A method for providing a power supply collapse signal, comprising:
applying a first voltage and a second voltage to threshold detection circuitry;
detecting when the second voltage drops to produce a detection signal;
causing supply collapse output circuitry to generate an output signal indicating the drop based on the detection signal; and
switching feedback circuitry to reduce leakage when the second voltage drops.

17. The method of claim 16, wherein the output signal is provided to a level shifter circuit.

18. The method of claim 17, wherein the output signal is provided to the level shifter circuit to reduce leakage from the level shifter circuit.

19. The method of claim 16, wherein the threshold detection circuitry comprises an inverter circuit.

20. The method of claim 19, wherein the inverter circuit comprises:
a P-channel metal-oxide-semiconductor field-effect-transistor (PMOS), wherein a gate of the PMOS is coupled to the second power supply, a source of the PMOS is coupled to the feedback circuitry, a body of the PMOS is coupled to the first power supply and a drain of the PMOS is coupled to the supply collapse output circuitry; and
an N-channel metal-oxide-semiconductor field-effect transistor (NMOS), wherein a gate of the NMOS is coupled to the second power supply and to the gate of the PMOS, a source of the NMOS is coupled to a ground, a body of the NMOS is coupled to the ground and a drain of the NMOS is coupled to the supply collapse output circuitry and to the drain of the PMOS.

21. The method of claim 16, wherein the feedback circuitry comprises a feedback transistor.

22. The method of claim 21, wherein the feedback transistor comprises an N-channel metal-oxide-semiconductor field-effect transistor (NMOS), wherein a gate of the NMOS is coupled to the supply collapse output circuitry, a source of the NMOS is coupled to the threshold detection circuitry, a body of the NMOS is coupled to a ground and a drain of the NMOS is coupled to the first power supply.

23. The method of claim 16, wherein the supply collapse output circuitry comprises a latch.

24. The method of claim 23, wherein the latch comprises:
an inverter that is coupled to the first power supply; and
a P-channel metal-oxide-semiconductor field-effect-transistor (PMOS), wherein a gate of the PMOS is coupled to an output of the inverter, a source of the PMOS is coupled to the first power supply, a body of the PMOS is coupled to the first power supply and a drain of the PMOS is coupled to an input of the inverter.

25. The method of claim 16, wherein the threshold detection circuitry and the feedback circuitry are coupled to a capacitor.

26. The method of claim 25, wherein the capacitor comprises a P-channel metal-oxide-semiconductor field-effect-transistor (PMOS), wherein a gate of the PMOS is coupled to a ground, a source of the PMOS is coupled to a drain of the PMOS, to the feedback circuitry and to the threshold detection circuitry.

27. The method of claim 16, wherein the threshold detection circuitry is coupled to a hysteresis circuit.

28. The method of claim 27, wherein the hysteresis circuit comprises:
a first N-channel metal-oxide-semiconductor field-effect transistor (NMOS), wherein a gate of the first NMOS is coupled to the second power supply and to the threshold detection circuitry, a source of the first NMOS is coupled to a ground, a body of the first NMOS is coupled to the ground and a drain of the first NMOS is coupled to the threshold detection circuitry; and
a second NMOS, wherein a gate of the second NMOS is coupled to the latch and to the threshold detection circuitry, a source of the second NMOS is coupled to the drain of the first NMOS, a body of the second NMOS is coupled to the ground and a drain of the NMOS is coupled to the first power supply.

29. The method of claim 16, wherein a resistor is coupled between the feedback circuitry and the threshold detection circuitry.

30. The method of claim 16, wherein an integrated circuit comprises the threshold detection circuitry, the supply collapse output circuitry and the feedback circuitry.

31. An apparatus for providing a power supply collapse signal, comprising:
means for applying a first voltage and a second voltage to threshold detection circuitry;
means for detecting when the second voltage drops to produce a detection signal;
means for causing supply collapse output circuitry to generate an output signal indicating the drop based on the detection signal; and
means for switching feedback circuitry to reduce leakage when the second voltage drops.

32. The apparatus of claim 31, wherein the output signal is provided to a level shifter circuit.

33. The apparatus of claim 31, wherein the threshold detection circuitry comprises an inverter circuit.

34. The apparatus of claim 31, wherein the feedback circuitry comprises a feedback transistor.

35. The apparatus of claim 31, wherein the supply collapse output circuitry comprises a latch.

36. The apparatus of claim 31, wherein the threshold detection circuitry and the feedback circuitry are coupled to a capacitor.

37. The apparatus of claim 31, wherein the threshold detection circuitry is coupled to a hysteresis circuit.

38. The apparatus of claim 31, wherein a resistor is coupled between the feedback circuitry and the threshold detection circuitry.

39. A computer-program product for providing a power supply collapse signal, comprising a non-transitory tangible computer-readable medium having instructions thereon, the instructions comprising:
code for causing a circuit to apply a first voltage and a second voltage to threshold detection circuitry;
code for causing the circuit to detect when the second voltage drops to produce a detection signal;
code for causing the circuit to cause supply collapse output circuitry to generate an output signal indicating the drop based on the detection signal; and
code for causing the circuit to switch feedback circuitry to reduce leakage when the second voltage drops.

40. The computer-program product of claim 39, wherein the output signal is provided to a level shifter circuit.

41. The computer-program product of claim 39, wherein the threshold detection circuitry comprises an inverter circuit.

42. The computer-program product of claim 39, wherein the feedback circuitry comprises a feedback transistor.

43. The computer-program product of claim 39, wherein the supply collapse output circuitry comprises a latch.

44. The computer-program product of claim 39, wherein the threshold detection circuitry and the feedback circuitry are coupled to a capacitor.

45. The computer-program product of claim 39, wherein the threshold detection circuitry is coupled to a hysteresis circuit.

46. The computer-program product of claim 39, wherein a resistor is coupled between the feedback circuitry and the threshold detection circuitry.
